(19) United States
(12) Patent Application Publication
(10) Pub. No.: US 2014/0070895 A1
(43) Pub. Date: Mar. 13, 2014

(54) MANUFACTURING METHOD OF QUANTUM INTERFERENCE DEVICE, QUANTUM INTERFERENCE DEVICE, ELECTRONIC APPARATUS, AND ATOM CELL MODULE

(71) Applicant: Seiko Epson Corporation, Tokyo (JP)

(72) Inventor: Koji CHINDO, Suwa (JP)

(73) Assignee: Seiko Epson Corporation, Tokyo (JP)

(21) Appl. No.: 14/017,700

(22) Filed: Sep. 4, 2013

(30) Foreign Application Priority Data
Sep. 10, 2012 (JP) 2012-198265

(51) Int. Cl. H03B 17/00

(52) U.S. Cl. CPC H03B 17/00
USPC 331/94.1; 29/600

(57) ABSTRACT

A manufacturing method of an atom oscillator (an example of a quantum interference device) includes assembling the atom oscillator (an example of the quantum interference device) by respectively disposing a gas cell, a semiconductor laser, a light detector, ICs of a circuit unit, heaters, and coils at desired locations, and adjusting at least one of currents which flow through the coils, and positions and shapes of the coils such that a frequency-temperature characteristic of a pair of resonance light beams becomes approximately flat.

### BACKGROUND

1. Technical Field

The present invention relates to a manufacturing method of a quantum interference device, a quantum interference device, an electronic apparatus, and an atom cell module.

2. Related Art

A cesium atom which is one kind of alkali metal atoms is known to have a ground level of 6S_{1/2} and two excitation levels of 6P_{1/2} and 6P_{3/2}, as shown in FIG. 22. In addition, each of levels of 6S_{1/2}, 6P_{1/2}, and 6P_{3/2} has a hyperfine structure of splitting into a plurality of energy levels. Specifically, 6S_{1/2} has two ground levels of F=3 and 4, 6P_{1/2} has two excitation levels of F=3 and 4, and 6P_{3/2} has four excitation levels of F=2, 3, 4 and 5.

For example, a cesium atom in the ground level of F=3 of 6S_{1/2} absorbs D2 rays and thus can transition to any excitation level of F=2, 3 and 4 of 6P_{3/2} but cannot transition to the excitation level of F=5. A cesium atom in the ground level of F=4 of 6S_{1/2} absorbs D2 rays and thus can transition to any excitation level of F=3, 4 and 5 of 6P_{3/2} but cannot transition to the excitation level of F=2. This depends on a transition selection rule when the electric dipole transition is assumed. In contrast, a cesium atom in either excitation level of F=3 and 4 of 6P_{3/2} emits D2 rays and thus can transition to a ground level (either of an original ground level and the other ground level) of F=3 or F=4 of 6S_{1/2}. Here, three levels (including two ground levels and one excitation level) including the two ground levels of F=3 and 4 of 6S_{1/2} and either excitation level of F=3 and 4 of 6P_{3/2} are called Λ type three levels since transition to a Λ type through absorption and emission of D2 rays can be performed. Similarly, three levels including the two ground levels of F=3 and 4 of 6S_{1/2} and either excitation level of F=3 and 4 of 6P_{1/2} form Λ type three levels since transition to a Λ type through absorption and emission of D1 rays can be performed.

On the other hand, a cesium atom in the excitation level of F=2 of 6P_{3/2} emits D2 rays and necessarily transitions to the ground level (original ground level) of F=3 of 6S_{1/2}, and, similarly, a cesium atom in the excitation level of F=5 of 6P_{3/2} emits D2 rays and necessarily transitions to the ground level (original ground level) of F=4 of 6S_{1/2}. In other words, three levels including the two ground levels of F=3 and 4 of 6S_{1/2} and the excitation level of F=2 or F=5 of 6P_{3/2} do not form Λ type three levels since transition to a Λ type through absorption and emission of D2 rays cannot be performed. In addition, alkali metal atoms other than the cesium atom are also known to have two ground levels and an excitation level forming a Λ type three levels in the same manner.

Meanwhile, it is known that, when a gaseous alkali metal atom is irradiated with resonance light (referred to as resonance light 1) with a frequency (oscillation frequency) corresponding to an energy difference between a first ground level (in the cesium atom, the ground level of F=3 of 6S_{1/2}) and an excitation level (in the cesium atom, for example, the excitation level of F=4 of 6P_{3/2}) forming the Λ type three levels and resonance light (referred to as resonance light 2) with a frequency (oscillation frequency) corresponding to an energy difference between a second ground level (in the cesium atom, the ground level of F=4 of 6S_{1/2}) and the excitation level, are applied to together, this leads to an overlapping state, that is a quantum coherence state (dark state), of the two ground levels and thus causes an electromagnetically induced transparency (EIT) phenomenon (also referred to as coherent population trapping (CPT) in some cases) in which excitation to an excitation level stops. A frequency difference between a pair of resonance light beams (the resonance light 1 and the resonance light 2) generating this EIT phenomenon exactly matches a frequency corresponding to an energy difference ΔE₁₂ between two ground levels of an alkali metal atom. For example, in a case of the cesium atom, since a frequency corresponding to an energy difference between the two ground levels is 9.192631770 GHz, when the cesium atom is irradiated with two kinds of laser light beams of D1 rays or D2 rays of with a frequency difference of 9.192631770 GHz together, the EIT phenomenon occurs.

Therefore, as shown in FIG. 23, when a gaseous alkali metal atom is irradiated with light with a frequency of f₁ and light with a frequency of f₂ together, an intensity of light which is transmitted through the alkali metal atom rapidly varies depending on whether or not these two light waves become a pair of resonance light beams so as to cause the EIT phenomenon of the alkali metal atom. A signal indicating the rapidly varying intensity of the transmitted light is referred to as an EIT signal (resonance signal), and a level of the EIT signal shows a peak value in a case where a frequency difference f₁−f₂ between a pair of resonance light beams exactly matches a frequency f₁₂ corresponding to ΔE₁₂. Therefore, an atom cell (gas cell) in which a gaseous alkali metal atom is sealed is irradiated with two light waves, and control is performed such that a peak top of the EIT signal is detected using a light detector, that is, a frequency difference f₁−f₂ between the two light waves exactly matches a frequency f₁₂ corresponding to ΔE₁₂, thereby implementing a high accuracy oscillator. A technique regarding this atom oscillator is disclosed in, for example, the specification of U.S. Pat. No. 6,320,472.

Meanwhile, in an atom oscillator including a gas cell, a temperature of the gas cell is generally controlled to a temperature range in which the best characteristics can be obtained. In a method of the related art, a heater is driven so as to warm an entire container (typically, made of metal) including the gas cell. In contrast, recently, a method of using a transparent conductive film in a heater has been proposed, and has been reported to be applied to an atom oscillator especially using the EIT phenomenon since the method is suitable for miniaturization, an appropriate temperature distribution can be easily obtained, and the like.

However, since a large heater current which fluctuates depending on an ambient air temperature flows around a part which is very close to the gas cell, there is a problem in that a magnetic field generated by the heater current fluctuates, and thus a frequency-temperature characteristic of the atom oscillator deteriorates. In addition, if an atom oscillator is miniaturized, the atom oscillator is easily influenced by an ambient air temperature, and thus there is a problem in that a temperature characteristic of a buffer gas such as neon (Ne) or argon (Ar) injected into the gas cell or a temperature characteristic of a circuit unit of the atom oscillator becomes revealed, and thereby a frequency-temperature characteristic also deteriorates.

### SUMMARY

An advantage of some aspects of the invention is to provide a quantum interference device capable of realizing a good frequency-temperature characteristic even if the quantum interference device is miniaturized, a manufacturing method thereof, an electronic apparatus using the quantum interference device, and an atom cell module used in the quantum interference device.

The invention can be implemented as the following forms or application examples.

### Application Example 1

This application example is directed to a manufacturing method of a quantum interference device including an atom cell in which an atom is sealed, a light generation unit that generates light including resonance light and irradiates the atom cell with the light, a light detection unit that detects light transmitted through the atom cell, a control unit that controls frequencies of the resonance light on the basis of a detection signal of the light detection unit, a heat generation unit that generates heat by allowing a current to flow therethrough so as to heat the atom cell, and a first magnetic field generation unit that generates a magnetic field inside the atom cell, the manufacturing method of the quantum interference device which causes a quantum interference state in the atom by using the resonance light, including assembling the quantum interference device by respectively disposing the atom cell, the light generation unit, the light detection unit, the control unit, the heat generation unit, and the first magnetic field generation unit at desired locations; and adjusting at least one of a current which flows through the first magnetic field generation unit, and a position and a shape of the first magnetic field generation unit such that a frequency-temperature characteristic of the quantum interference device becomes approximately flat.

Generally, if an ambient air temperature fluctuates, a current which flows through the heat generation unit fluctuates depending on a fluctuation amount, and if the current which flows through the heat generation unit fluctuates, a magnetic field intensity inside the atom cell also fluctuates. In addition, when the magnetic field intensity inside the atom cell fluctuates, a frequency of resonance light fluctuates. Therefore, even if a temperature characteristic of the atom cell or the circuit unit is flat, a frequency-temperature characteristic of the quantum interference device has a slope due to the fluctuation (fluctuation in the magnetic field intensity) in the current which flows through the heat generation unit. Therefore, it is possible to make a comprehensive frequency-temperature characteristic of the quantum interference device flat by making a slope of a frequency-temperature characteristic of the quantum interference device caused by the fluctuation (the fluctuation in the magnetic field intensity) in a current which flows through the heat generation unit reverse to a slope of a frequency-temperature characteristic of the quantum interference device caused by a temperature characteristic of the atom cell or the circuit unit. A frequency of the resonance light is known to be represented by a quadric of a magnetic field intensity inside the atom cell, and thus a frequency-temperature characteristic of the quantum interference device caused by the fluctuation (the fluctuation in the magnetic field intensity) in a current which flows through the heat generation unit has a slope corresponding to a direction and an intensity of the magnetic field inside the atom cell. The adjustment of a direction or an intensity of the magnetic field inside the atom cell can be realized by adjusting a current which flows through the first magnetic field generation unit or a position and a shape of the first magnetic field generation unit.

Therefore, according to the manufacturing method of a quantum interference device of this application example, it is possible to implement a quantum interference device capable of realizing a good frequency-temperature characteristic even if the quantum interference device is miniaturized.

### Application Example 2

The manufacturing method of a quantum interference device according to the application example may be configured such that the method further includes measuring a frequency-temperature characteristic of the quantum interference device assembled in the assembling of the quantum interference device, and, in the adjusting, a value of a current which flows through the first magnetic field generation unit is calculated based on a measurement result in the measuring of the frequency-temperature characteristic, and information which can specify a correspondence relationship between a magnetic field generated by the first magnetic field generation unit and frequencies of the resonance light.

According to the manufacturing method of a quantum interference device of this application example, it is possible to understand a direction or an intensity of a magnetic field which is to be generated by the first magnetic field generation unit for correcting the frequency-temperature characteristic measured in the measuring based on information (information of a quadric) which can specify a correspondence relationship between a magnetic field generated by the first magnetic field generation unit and frequencies of the resonance light. Thus, a value of a current which flows through the first magnetic field generation unit can be calculated. Therefore, it is possible to implement a quantum interference device capable of realizing a good frequency-temperature characteristic by storing this current value and making the current flow through the first magnetic field generation unit.

### Application Example 3

The manufacturing method of a quantum interference device according to the application example may be configured such that the quantum interference device further includes a second magnetic field generation unit that generates a magnetic field inside the atom cell by allowing at least a part of a current which flows through the heat generation unit to flow therethrough, and, in the assembling, the atom cell, the light generation unit, the light detection unit, the control unit, the heat generation unit, the first magnetic field generation unit, and the second magnetic field generation unit are respectively disposed at desired positions so as to assemble the quantum interference device.

According to the manufacturing method of a quantum interference device of this application example, a magnetic field generated by the second magnetic field generation unit fluctuates depending on fluctuation in a current which flows through the heat generation unit, thereby widening or narrowing a fluctuation range of a magnetic field intensity inside the atom cell. As a result, it is possible to change a slope of a frequency-temperature characteristic of the quantum interference device caused by fluctuation (fluctuation in a magnetic field intensity) in a current which flows through the heat generation unit. Therefore, the application example is effective even in a case where it is difficult to make a frequency-temperature characteristic of the quantum interference device flat only with adjustment of the first magnetic field generation unit since a magnetic field generated by the first magnetic field generation unit is too weak or too strong.

### Application Example 4

The manufacturing method of the quantum interference device according to the application example may be configured such that, in the adjusting, at least one of a current which flows through the second magnetic field generation unit, and a position and a shape of the second magnetic field generation unit is adjusted such that a frequency-temperature characteristic of the quantum interference device becomes approximately flat.

According to the manufacturing method of a quantum interference device of this application example, a direction or an intensity of a magnetic field generated by the first magnetic field generation unit can be adjusted, and a direction or a fluctuation width of a magnetic field generated by the second magnetic field generation unit can be adjusted, thereby easily making a frequency-temperature characteristic of the quantum interference device flat.

### Application Example 5

This application example is directed to a quantum interference device which causes a quantum interference state in an atom by using resonance light, including an atom cell in which the atom is sealed; a light generation unit that generates light including the resonance light and irradiates the atom cell with the light; a light detection unit that detects light transmitted through the atom cell; a control unit that controls frequencies of the resonance light on the basis of a detection signal of the light detection unit; a heat generation unit that generates heat by allowing a current to flow therethrough so as to heat the atom cell; and a first magnetic field generation unit that generates a magnetic field inside the atom cell, in which at least one of a current which flows through the first magnetic field generation unit and a position and a shape of the first magnetic field generation unit is adjusted such that a frequency temperature characteristic of the quantum interference device becomes approximately flat.

### Application Example 6

This application example is directed to an electronic apparatus including the quantum interference device.

### Application Example 7

This application example is directed to an atom cell module including an atom cell in which the atom is sealed; a heat generation unit that generates heat by allowing a current to flow therethrough so as to heat the atom cell; and a first magnetic field generation unit that generates a magnetic field inside the atom cell, in which at least one of a current which flows through the first magnetic field generation unit, and a position and a shape of the first magnetic field generation unit is adjusted such that a frequency-temperature characteristic of resonance light causing a quantum interference state in the atom becomes approximately flat.

### BRIEF DESCRIPTION OF THE DRAWINGS

The invention will be described with reference to the accompanying drawings, wherein like numbers reference like elements.

FIG. 1 is a functional block diagram of an atom oscillator according to a first embodiment.

FIG. 2 is a diagram illustrating a specific configuration example of the atom oscillator according to the first embodiment.

FIGS. 3A and 3B are diagrams illustrating an example of a gas cell module structure in the first embodiment.

FIG. 4A is a diagram illustrating Zeeman splitting energy levels, and FIG. 4B is a diagram illustrating an example of splitting EIT signals.

FIG. 5 is a schematic diagram illustrating an example of a frequency spectrum of emission light of a semiconductor laser.

FIG. 6 is a diagram illustrating an example of a relationship between directions of currents which flow through heaters and coils and a direction of a magnetic field generated inside a gas cell.

FIG. 7A is a diagram illustrating a relationship between an ambient air temperature and a heater current, and FIG. 7B is a diagram illustrating a relationship between an ambient air temperature and a magnetic field intensity.

FIG. 8 is a diagram illustrating a relationship between a magnetic field intensity and a frequency difference between a pair of resonance light beams.

FIG. 9 is a diagram illustrating a relationship between an ambient air temperature and a frequency difference between a pair of resonance light beams.

FIG. 10 is a flowchart illustrating an example of a manufacturing method of the atom oscillator according to the first embodiment.

FIGS. 11A to 11D are diagrams illustrating examples of a frequency-temperature characteristic of an output signal of the atom oscillator.

FIG. 12 is a functional block diagram of an atom oscillator according to a second embodiment.

FIG. 13 is a diagram illustrating a specific configuration example of the atom oscillator according to the second embodiment.

FIGS. 14A and 14B are diagrams illustrating an example of a gas cell module structure in the second embodiment.

FIG. 15 is a diagram illustrating an example of a relationship between directions of currents which flow through heaters and coils and directions of magnetic fields generated inside a gas cell.

FIG. 16 is a diagram illustrating a relationship between a magnetic field intensity and a frequency difference between a pair of resonance light beams.

FIG. 17 is a diagram illustrating a relationship between an ambient air temperature and a frequency difference between a pair of resonance light beams.

FIG. 18 is a flowchart illustrating an example of a manufacturing method of the atom oscillator according to the second embodiment.

FIG. 19 is a functional block diagram of an electronic apparatus of the present embodiment.

FIG. 20 is a schematic diagram of an electronic apparatus of the present embodiment.

FIGS. 21A and 21B are schematic diagrams illustrating frequency spectra of emission light of a semiconductor laser in a modification example.

FIG. 22 is a diagram schematically illustrating energy levels of a cesium atom.

FIG. 23 is a schematic diagram illustrating an example of an EIT signal.

### DESCRIPTION OF EXEMPLARY EMBODIMENTS

Hereinafter, embodiments of the invention will be described in detail with reference to the drawings. In addition, the embodiments described below are not intended to improperly limit content of the invention recited in the appended claims. Further, all constituent elements described below are not essential constituent elements of the invention.

Hereinafter, an atom oscillator which is an example of the quantum interference device will be described as an example.

### 1. Atom Oscillator

### 1-1. First embodiment

### Functional Configuration of Atom Oscillator

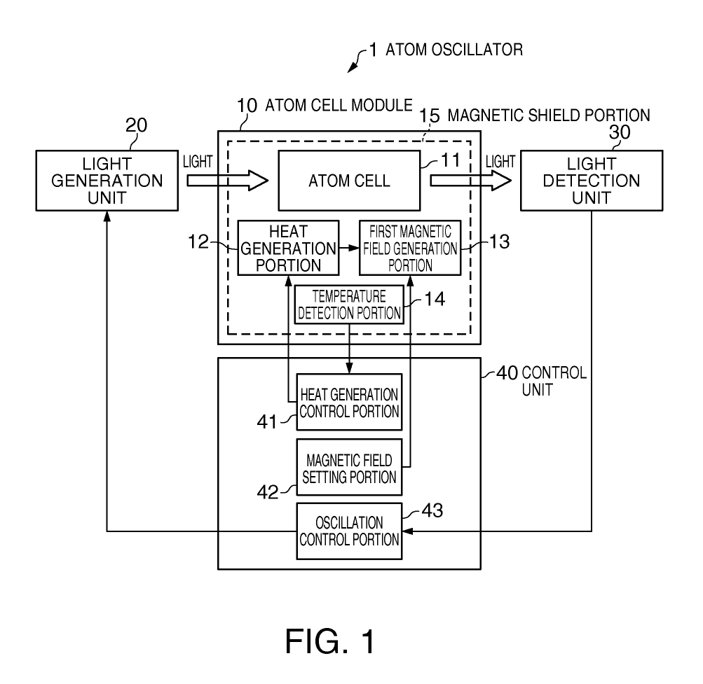

FIG. 1 is a functional block diagram of an atom oscillator according to a first embodiment. As shown in FIG. 1, an atom oscillator 1 according to the first embodiment includes an atom cell module 10, a light generation unit 20, a light detection unit 30, and a control unit 40. In addition, the atom oscillator of the present embodiment may have a configuration in which some of the constituent elements (the respective portions) of FIG. 1 are appropriately omitted or changed, or other constituent elements are added.

The atom cell module 10 includes an atom cell 11, a heat generation portion 12, a first magnetic field generation portion 13, and a temperature detection portion 14. The atom cell module 10 may further include a magnetic shield portion 15.

The atom cell 11 is a cell in which an atom (for example, an alkali metal atom such as a sodium (Na) atom, a rubidium (Rb) atom, or a cesium (Cs) atom) having Λ type three levels is sealed in a container made of a transparent member such as glass. Light generated by the light generation unit 20 is incident to the atom cell 11, and some of the incident light is transmitted through the atom cell 11.

The heat generation portion 12 generates heat when a current flows therethrough, and heats the atom cell 11. The heat generation portion 12 may be implemented using, for example, a heater which generates a heat quantity according to a current quantity. For example, conductive and light-transmissive heaters may be disposed on an incidence surface and an emission surface of light of the atom cell 11. The conductive and light-transmissive heaters may be implemented using a transparent electrode material such as indium tin oxide (ITO), indium zinc oxide (IZO), In₃O₃, SnO₂, SnO₂ containing Sb, or ZnO containing Al.

The first magnetic field generation portion 13 generates a magnetic field inside the atom cell 11. The magnetic field generation portion 13 may be implemented using, for example, a coil, and may generate a desired magnetic field by adjusting a position or a shape of the coil (for example, a coil winding direction, the number of turns, a diameter, and the like), a magnitude or a direction of a current, and the like.

The temperature detection portion 14 is disposed at a predetermined position and detects temperature. The temperature detection portion 14 may be disposed so as to come into contact with, for example, the heat generation portion 12 or the atom cell 11. The temperature detection portion 14 may be implemented using, for example, a temperature sensor such as a thermistor or a thermocouple.

The magnetic shield portion 15 may shield at least the atom cell 11, the heat generation portion 12, and the magnetic field generation portion 13 from an external magnetic field, and, further, may also shield the temperature detection portion 14 from an external magnetic field.

The light generation unit 20 generates light including resonance light which causes the atom sealed in the atom cell 11 to resonate, and irradiates the atom cell 11 with the light. The light generation unit 20 may be implemented using, for example, a semiconductor laser. As the semiconductor laser, a surface emitting laser such as an edge emitting laser or a vertical cavity surface emitting laser (VCSEL), or the like may be used.

The light detection unit 30 detects light which is transmitted through the atom cell 11. The light detection unit 30 may be implemented using, for example, a photodiode (PD) which outputs a detection signal corresponding to an intensity of received light.

The control unit 40 includes a heat generation control portion 41, a magnetic field setting portion 42, and an oscillation control portion 43, and may be implemented using, for example, a general purpose microprocessor or a dedicated circuit.

The heat generation control portion 41 controls a current which flows through the heat generation portion 12 in response to a detection signal of the temperature detection portion 14. The heat generation control portion 41 controls a generated heat quantity of the heat generation portion 12 such that an internal temperature of the atom cell 11 is maintained to be approximately constant.

The magnetic field setting portion 42 sets the magnitude of a magnetic field generated by the first magnetic field generation portion 13. A constant magnetic field (normal magnetic field) is generated at each position inside the atom cell 11 by the magnetic field setting portion 42. The magnetic field setting portion 42 may generate a normal magnetic field, for example, by making a constant amount of current flow through the first magnetic field generation portion 13.

The oscillation control portion 43 controls a frequency of light generated by the light generation unit 20 on the basis of a detection signal of the light detection unit 30. The light generation unit 20 is controlled so as to generate resonance light by the oscillation control portion 43.

Particularly, in the present embodiment, a magnetic field generated by the first magnetic field generation portion 13 is adjusted such that a frequency-temperature characteristic of resonance light generated by the light generation unit 20 becomes approximately flat. For example, a magnetic field generated by the first magnetic field generation portion 13 may be adjusted by adjusting at least one of a position and a shape of the first magnetic field generation portion 13, and a magnitude and a direction of a current.

In addition, in relation to the atom oscillator, for example, the light generation unit 20 may be controlled so as to generate a pair of resonance light beams which cause an EIT phenomenon in the atom sealed in the atom cell 11, or the atom cell 11 may be accommodated in a cavity resonator (microwave cavity), the light generation unit 20 may be controlled so as to generate resonance light for the atom sealed in the atom cell 11, and an optical microwave double resonance phenomenon caused by applying microwaves to the cavity resonator may be used.

### Specific Configuration of Atom Oscillator

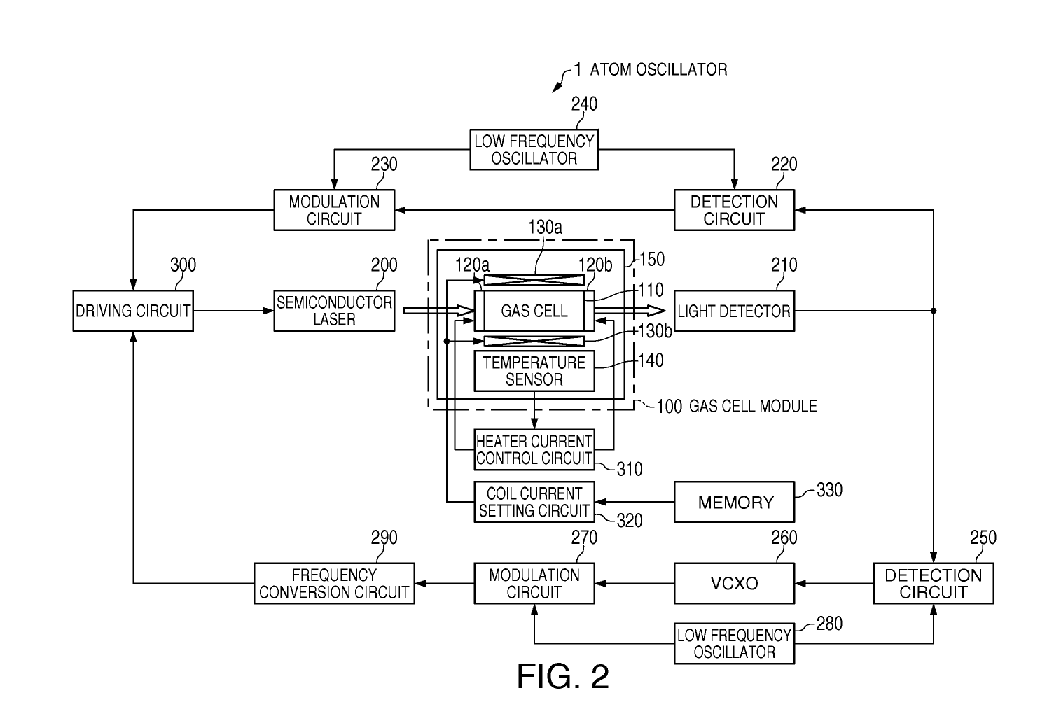

FIG. 2 is a specific configuration example of the atom oscillator 1 according to the first embodiment. As shown in FIG. 2, the atom oscillator 1 includes a gas cell module 100, a semiconductor laser 200, a light detector 210, a detection circuit 220, a modulation circuit 230, a low frequency oscillator 240, a detection circuit 250, a voltage controlled crystal oscillator (VCXO) 260, a modulation circuit 270, a low frequency oscillator 280, a frequency conversion circuit 290, a driving circuit 300, a heater current control circuit 310, a coil current setting circuit 320, and a memory 330 (storage unit). In addition, the atom oscillator according to the present embodiment may have a configuration in which some of the constituent elements (the respective portions) of FIG. 2 may be omitted or changed, or other constituent elements may be added.

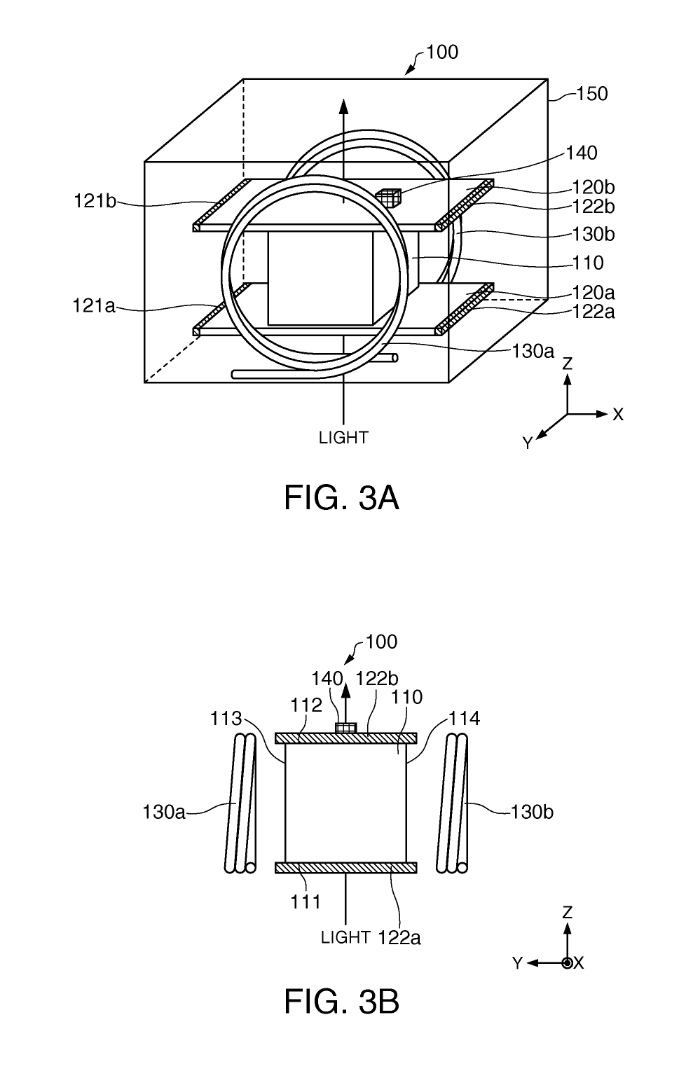

The gas cell module 100 corresponds to the atom cell module 10 shown in FIG. 1, and includes a gas cell 110, heaters 120a and 120b, coils 130a and 130b, a temperature sensor 140, and a magnetic shield 150. FIGS. 3A and 3B show an example of a structure of the gas cell module 100. FIG. 3A is a perspective view of the gas cell module 100, and FIG. 3B is a side view of the gas cell module 100. In FIGS. 3A and 3B, for convenience of description, three axes (the X axis, the Y axis, and the Z axis) perpendicular to one another are shown together, and FIG. 3B is a side view of the gas cell module 100 when viewed from the positive direction of the X axis.

The gas cell 110 corresponds to the atom cell 11 of FIG. 1, and is a cell in which a buffer gas such as neon (Ne) or argon (Ar) is sealed along with a gaseous alkali metal atom in a container made of a transparent member such as glass. In the present embodiment, the gas cell 110 is rectangular parallelepiped, and light is incident on a predetermined position (for example, a central point) of one surface (incidence surface) 111 perpendicular to the Z axis, and the light transmitted through the gas cell 110 is emitted from a predetermined position (for example, a central point) of the other surface (emission surface) 112. Further, the gas cell 110 may have other shapes such as a column.

Both of the two heaters 120a and 120b have a plate shape, and are respectively disposed so as to overlap the incidence surface 111 and the emission surface 112 of the gas cell 110. Electrodes 121a and 122a are respectively provided at both ends of the heater 120a, and a current flows from the electrode 122a to the electrode 121a or a current flows in a reverse direction thereto so as to generate heat, thereby heating the gas cell 110. Electrodes 121b and 122b are provided at both ends of the heater 120b, and a current flows from the electrode 121b to the electrode 122b or a current flows in a reverse direction thereto so as to generate heat, thereby heating the gas cell 110. In the present embodiment, the heaters 120a and 120b are formed using a transparent conductive film, and light transmitted through the heater 120a is incident on the gas cell 110, and the light transmitted through the gas cell 110 is transmitted through the heater 120b and is emitted. The two heaters 120a and 120b correspond to the heat generation portion 12 of FIG. 1.

The temperature sensor 140 corresponds to the temperature detection portion 14 of FIG. 1, and is disposed on the surface of the heater 120b in the present embodiment. However, the temperature sensor 140 may be disposed on the surface of the heater 120a or the gas cell 110.

The two coils 130a and 130b are disposed so as to face two surfaces 113 and 114 perpendicular to (perpendicular to the Y axis) both of the incidence surface 111 and the emission surface 112 of the gas cell 110 respectively. The two coils 130a and 130b correspond to the first magnetic field generation portion 13 of FIG. 1, and constant magnetic fields (normal magnetic fields) according to directions and magnitudes of currents which flow through the two coils 130a and 130b are generated at respective positions inside the gas cell 110. However, magnetic fields according to heater currents (the currents which flow through the heaters 120a and 120b) which fluctuate depending on an ambient air temperature are also generated at the respective positions inside the gas cell 110, and thus the magnetic fields at the respective positions inside the gas cell 110 fluctuate in a range depending on a fluctuation range of the ambient air temperature.

The gas cell 110, the heaters 120a and 120b, the coils 130a and 130b, and the temperature sensor 140 are covered by the magnetic shield 150. The magnetic shield 150 corresponds to the magnetic shield portion 15 of FIG. 1. In addition, the magnetic shield 150 is not typically transparent, but, in FIG. 3A, the magnetic shield 150 is shown to be transparent in order to reveal a structure of the gas cell module 100. Further, in FIG. 3B, the magnetic shield 150 is not shown.

Referring to FIG. 2 again, the semiconductor laser 200 corresponds to the light generation unit 20 of FIG. 1, and generates light including two light waves which are a pair of resonance light beams causing an EIT phenomenon in the alkali metal atom included in the gas cell 110. The light generated by the semiconductor laser 200 is incident on the gas cell 110.

The light detector 210, which corresponds to the light detection unit 30 of FIG. 1, allows light transmitted through the gas cell 110 to be incident thereon and outputs a detection signal according to the intensity of the incident light. The output signal of the light detector 210 is input to the detection circuit 220 and the detection circuit 250.

The detection circuit 220 performs synchronous detection of the output signal of the light detector 210 by using an oscillation signal of the low frequency oscillator 240 which oscillates at a low frequency of about several Hz to several hundreds of Hz. The modulation circuit 230 modulates the output signal of the detection circuit 220 by using an oscillation signal (the same signal as the oscillation signal supplied to the detection circuit 220) of the low frequency oscillator 240 as a modulation signal so as to be output to the driving circuit 300 such that the synchronous detection can be performed by the detection circuit 220. The modulation circuit 230 may be implemented using a frequency mixer, a frequency modulation (FM) circuit, an amplitude modulation (AM) circuit, or the like.

The detection circuit 250 performs synchronous detection of the output signal of the light detector 210 by using an oscillation signal of the low frequency oscillator 280 which oscillates at a low frequency of about several Hz to several hundreds of Hz. In addition, an oscillation frequency of the voltage controlled crystal oscillator (VCXO) 260 is finely adjusted depending on the magnitude of the output signal of the detection circuit 250. The voltage controlled crystal oscillator (VCXO) 260 oscillates, for example, at about several MHz to several tens of MHz.

The modulation circuit 270 modulates the output signal of the voltage controlled crystal oscillator (VCXO) 260 by using an oscillation signal (the same signal as the oscillation signal supplied to the detection circuit 250) of the low frequency oscillator 280 as a modulation signal such that the synchronous detection can be performed by the detection circuit 250. The modulation circuit 270 may be implemented using a frequency mixer, a frequency modulation (FM) circuit, an amplitude modulation (AM) circuit, or the like.

The frequency conversion circuit 290 performs frequency conversion on the output signal of the modulation circuit 270 at a constant frequency conversion rate so as to be output to the driving circuit 300. The frequency conversion circuit 290 may be implemented using, for example, a phase locked loop (PLL) circuit.

The driving circuit 300 sets a bias current of the semiconductor laser 200, and finely adjusts the bias current in response to the output signal of the modulation circuit 230 so as to be supplied to the semiconductor laser 200. In other words, a central wavelength λ₀ (a central frequency f₀) of light generated by the semiconductor laser 200 is finely adjusted through a feedback loop (a first feedback loop) passing through the semiconductor laser 200, the gas cell 110, the light detector 210, the detection circuit 220, the modulation circuit 230, and the driving circuit 300. Specifically, feedback control is performed on a wavelength λ₁ (=v/f₁ where v is light velocity) corresponding to an energy difference between the excitation level and one ground level of the alkali metal atom and a wavelength λ₂ (=v/f₂) corresponding to an energy difference between the excitation level and the other ground level through the first feedback loop such that the central wavelength λ₀ (=v/f₀) of the emission light of the semiconductor laser 200 is substantially the same as (λ₁+λ₂)/2 (the central frequency f₀ is substantially the same as (f₁+f₂)/2).

The driving circuit 300 superimposes a current (modulated current) with an output frequency component (a modulated frequency fₘ) of the frequency conversion circuit 290 on the bias current so as to be supplied to the semiconductor laser 200. Frequency modulation is applied to the semiconductor laser 200 by the modulated current, and thus not only light with the central frequency fₒ but also light with frequencies f₀±fₘ, f₀±2fₘ, . . . frequencies of which are deviated by fₘ on both sides thereof, are generated. In addition, light with a frequency f₀+fₘ and light with a frequency f₀−fₘ are finely adjusted so as to become a pair of resonance light beams causing an EIT phenomenon in the alkali metal atom sealed in the gas cell 110 through a feedback loop (a second feedback loop) passing through the semiconductor laser 200, the gas cell 110, the light detector 210, the detection circuit 250, the voltage controlled crystal oscillator (VCXO) 260, the modulation circuit 270, the frequency conversion circuit 290, and the driving circuit 300.

In addition, the circuit formed by the detection circuit 220, the modulation circuit 230, the low frequency oscillator 240, the detection circuit 250, the voltage controlled crystal oscillator (VCXO) 260, the modulation circuit 270, the low frequency oscillator 280, the frequency conversion circuit 290, and the driving circuit 300 corresponds to the oscillation control portion 43 of FIG. 1.

The heater current control circuit 310 corresponds to the heat generation control portion 41 of FIG. 1, and controls currents which flow through the heaters 120a and 120b according to a detection temperature of the temperature sensor 140 such that a temperature of the gas cell 110 is maintained to be constant. Specifically, the heater current control circuit 310 reduces currents which flow through the heaters 120a and 120b when a detection temperature of the temperature sensor 140 slightly increases due to an increase in an ambient air temperature, and, conversely, increases currents which flow through the heaters 120a and 120b when a detection temperature of the temperature sensor 140 slightly decreases due to a decrease in an ambient air temperature.

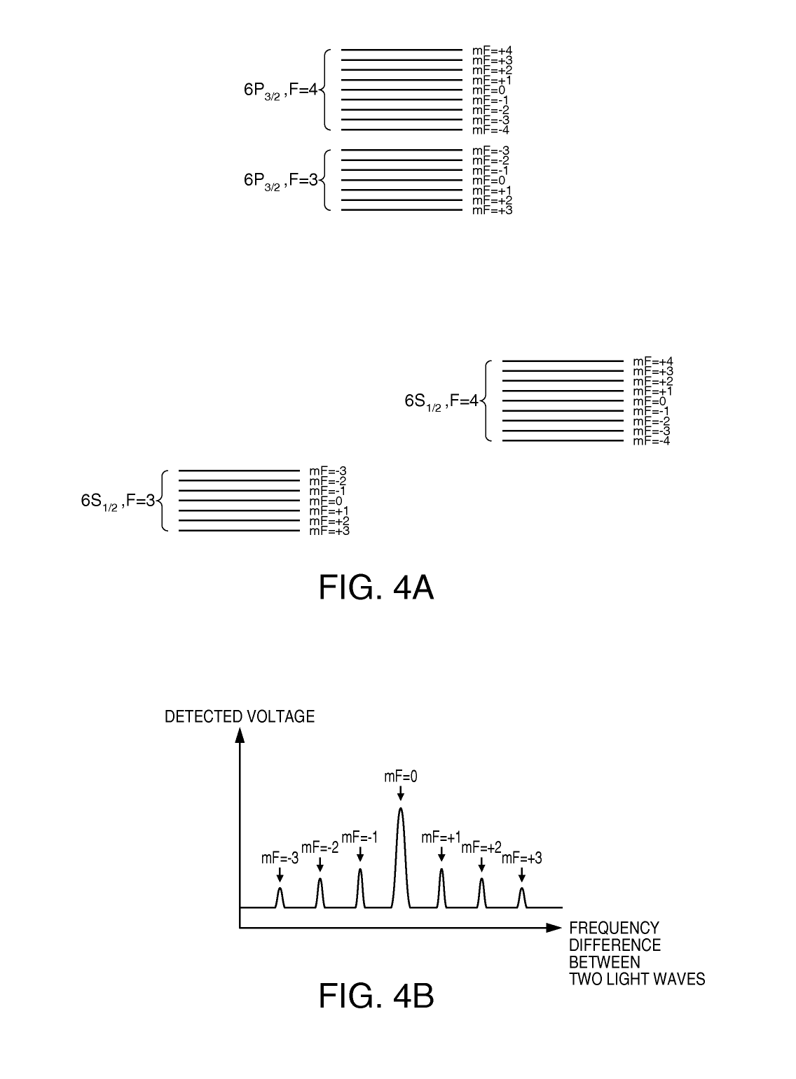

The coil current setting circuit 320 corresponds to the magnetic field setting portion 42 of FIG. 1, and sets an amount of currents which flow through the coils 130a and 130b according to set information stored in the memory 330 (nonvolatile memory). Thus, the coils 130a and 130b generate normal magnetic fields of a desired intensity according to the amount of currents inside the gas cell 110. The normal magnetic fields are applied to the gas cell 110, and thus each energy level of the alkali metal atom splits into (2F+1) levels (Zeeman splitting). For example, as shown in FIG. 4A, in a case of the cesium atom, the ground level of 6S_{1/2} and F=3 or the excitation level of 6P_{3/2} and F=3 splits into seven levels corresponding to the magnetic quantum number mF=0, ±1, ±2 and ±3, and the ground level of 6S_{1/2} and F=4 or the excitation level of 6P_{3/2} and F=4 splits into nine levels corresponding to the magnetic quantum number mF=0, ±1, ±2, ±3 and ±4.

A frequency (frequency difference) of a pair of resonance light beams causing an EIT phenomenon in an alkali metal atom is known to be different for each magnetic quantum number mF. In other words, in a state in which a magnetic field is applied to the gas cell 110, when a frequency difference between two light waves emitted by the semiconductor laser 200 is swept, a plurality of peaks, that is, a plurality of EIT signals are observed in an output of the light detector 210. For example, as shown in FIG. 4B, in a case of the cesium atom, seven EIT signals corresponding to the magnetic quantum number mF=0, ±1, ±2 and ±3 are observed. In FIG. 4B, the transverse axis expresses a swept frequency difference between two light waves, and the longitudinal axis expresses an intensity of light detected by the light detector 210. As shown in FIG. 4B, generally, since the intensity of an EIT signal corresponding to mF=0 is the greatest, it is effective to control a frequency difference between a pair of resonance light beams so as to generate an EIT signal corresponding to mF=0.

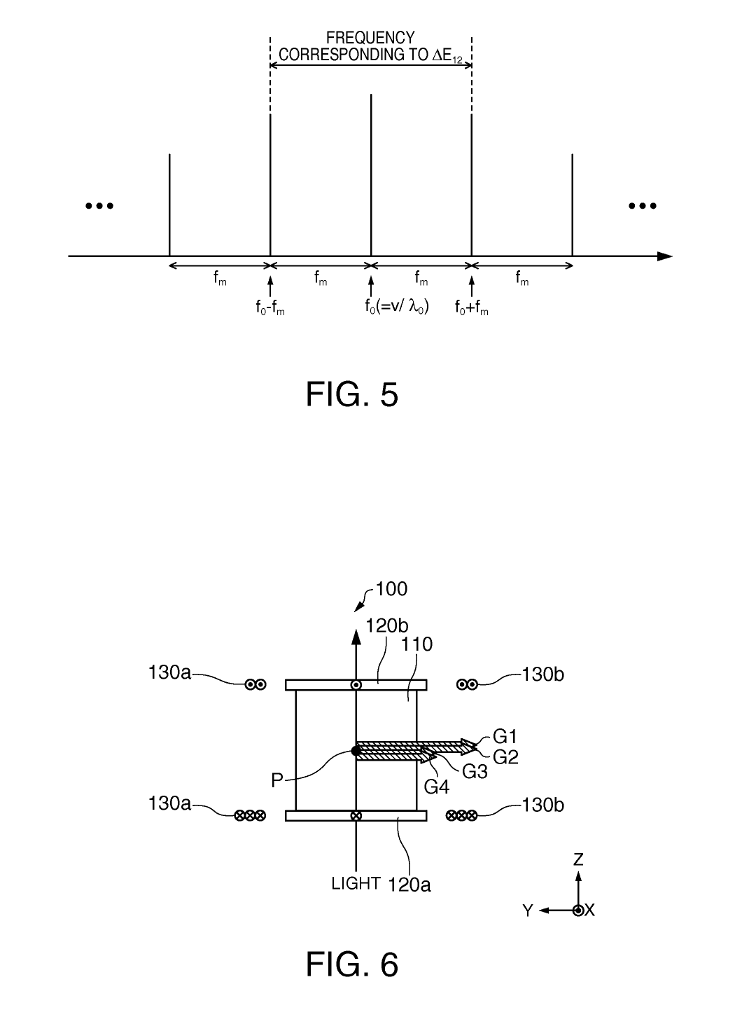

Therefore, the atom oscillator 1 according to the present embodiment performs control such that, for example, an alkali metal atom with either of two ground levels of the magnetic quantum number mF=0 causes an EIT phenomenon. Specifically, through the second feedback loop, feedback control is performed such that a frequency difference (=2fₘ) between light with a frequency f₀+fₘ and light with a frequency f₀−fₘ matches a frequency corresponding to an energy difference ΔE₁₂ between two ground levels of the magnetic quantum number mF=0 of the alkali metal atom. For example, if the alkali metal atom is a cesium atom, since a frequency corresponding to ΔE₁₂ is 9.192631770 GHz+Δ Hz (Δ is a frequency represented by a quadric of magnetic field intensity), a frequency of an output signal of the frequency conversion circuit 290 is stabilized in a state of matching 4.596315885 GHz+Δ/2 Hz. FIG. 5 shows an example of a frequency spectrum of emission light of the semiconductor laser 200. In FIG. 5, the transverse axis expresses a frequency of light, and the longitudinal axis expresses an intensity of light.

### Frequency-Temperature Characteristic of Atom Oscillator

Generally, a frequency difference between a pair of resonance light beams has a positive-slope or negative-slope temperature characteristic depending on the kind or an amount of buffer gas sealed in the gas cell 110. For example, in a case where only neon (Ne) is injected in the gas cell 110 as a buffer gas, a temperature characteristic of a frequency difference between a pair of resonance light beams has a positive slope with respect to a temperature increase, and, in a case where only argon (Ar) is injected in the gas cell 110 as a buffer gas, a temperature characteristic of a frequency difference between a pair of resonance light beams has a negative slope with respect to a temperature increase. Since a frequency of an output signal (for example, an output signal of the voltage controlled crystal oscillator (VCXO) 260) of the atom oscillator 1 is defined by the frequency difference between a pair of resonance light beams, if a temperature characteristic of the frequency difference between a pair of resonance light beams has a slope, a frequency-temperature characteristic of the output signal of the atom oscillator 1 also has the same slope. For example, when neon (Ne) and argon (Ar) are mixed at an appropriate ratio and are sealed in the gas cell 110, a temperature characteristic of the frequency difference between a pair of resonance light beams can be theoretically flat. However, practically, it is difficult for a frequency-temperature characteristic of an output signal of the atom oscillator 1 to be flat due to errors of an amount of buffer gases to be injected, temperature characteristics of constituent elements forming the circuit unit of the atom oscillator 1, and the like. The frequency-temperature characteristic of an output signal of the atom oscillator 1, therefore, has a slight slope.

However, as described above, magnetic fields (normal magnetic fields) generated by currents (coil currents) which flow through the coils 130a and 130b and magnetic fields (varying magnetic fields) generated by currents (heater currents) which flow through the heaters 120a and 120b are applied to the gas cell 110. FIG. 6 is a diagram illustrating an example of a relationship between directions of currents which flow through the heaters 120a and 120b and the coils 130a and 130b and directions of magnetic fields generated inside the gas cell 110. FIG. 6 is a cross-sectional view which is viewed from the positive direction of the X axis when the gas cell module 100 of FIGS. 3A and 3B is cut at a surface which is parallel to the YZ plane and includes a light path. In addition, in FIG. 6, the magnetic shield 150 is not shown.

As shown in FIG. 6, a current flows through the coil 130a clockwise when viewed from, for example, the +Y direction, and thus a magnetic field G1 in the −Y direction is generated at a point P (for example, a central position inside the gas cell 110) on the light path inside the gas cell 110. Similarly, a current also flows through the coil 130b clockwise when viewed from the +Y direction, and thus a magnetic field G2 in the −Y direction is generated at the point P.

A current flows through the heater 120a, for example, in the −X direction (from the electrode 122a to the electrode 121a), and thus a magnetic field G3 in the −Y direction is generated at the point P. On the other hand, a current flows through the heater 120b, for example, in the +X direction (from the electrode 121b to the electrode 122b), and thus a magnetic field G4 in the −Y direction is generated at the point P.

According to the quantum interference device of this application example, the directions of the magnetic fields (normal magnetic fields) G1 and G2 generated by the currents (coil currents) which flow through the coils 130a and 130b are the same as the directions of the magnetic fields (varying fields) G3 and G4 generated by the currents (heater currents) which flow through the heaters 120a and 120b.

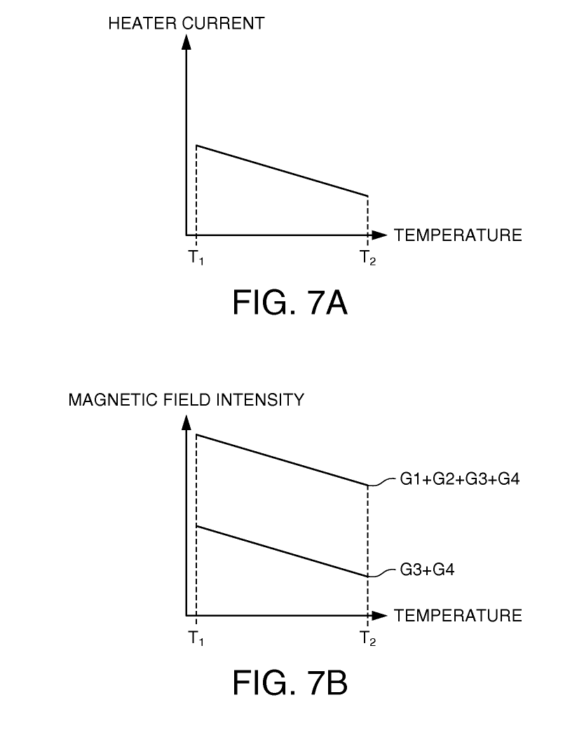

Here, in a case where an ambient air temperature fluctuates in a range of T₁ to T₂, the heater currents approximately linearly decrease with respect to a temperature increase in order to maintain the gas cell 110 at an approximately constant temperature (refer to FIG. 7A). In addition, the magnetic fields G3 and G4 approximately linearly decrease with respect to a decrease in the heater currents, and thus the magnetic field G3+G4 approximately linearly decreases with respect to a temperature increase (refer to FIG. 7B). The magnetic fields G1 and G2 are constant even if an ambient air temperature varies, and thus a sum total G1+G2+G3+G4 of the magnetic fields applied to the point P inside the gas cell 110 also approximately linearly decreases with respect to a temperature increase (refer to FIG. 7B).

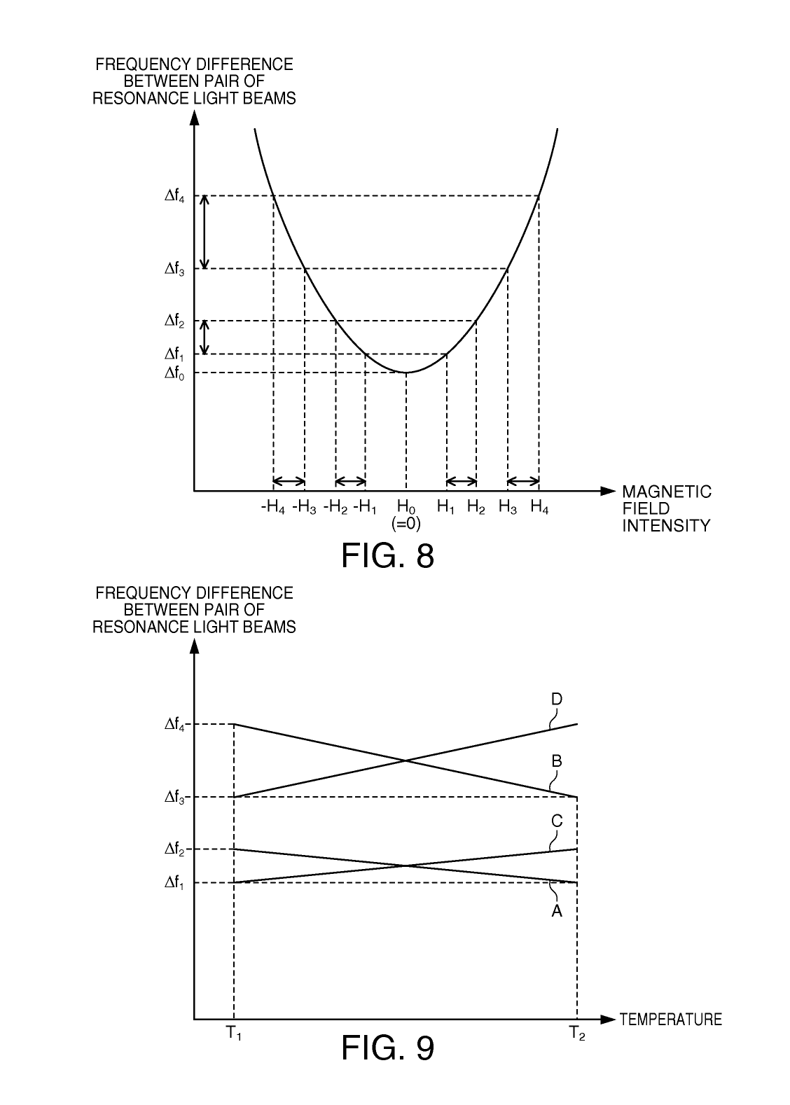

On the other hand, if the intensity of the magnetic field applied to the gas cell 110 fluctuates, two Zeeman splitting ground levels of the alkali metal atom fluctuate, and thus a frequency difference between a pair of resonance light beams also fluctuates. As shown in FIG. 8, a frequency difference between a pair of resonance light beams is the minimum when a magnetic field intensity is 0 (for example, in a case of the cesium atom, 9.192631770 GHz) and varies in a quadric manner with respect to the magnetic field intensity. In a case where an ambient air temperature fluctuates in a range of T₁ to T₂, for example, if a magnetic field intensity (the magnitude of G1+G2+G3+G4) at the point P fluctuates in a range of H₂ to H₁, a frequency difference between a pair of resonance light beams decreases with respect to a temperature increase, and fluctuates in a range of Δf₂ to Δf₄ (refer to a graph A of FIG. 9). In addition, for example, if a magnetic field intensity at the point P fluctuates in a range of H₄ to H₃, a frequency difference between a pair of resonance light beams more rapidly decreases with respect to a temperature increase, and fluctuates in a range of Δf₄ to Δf₃ (refer to a graph B of FIG. 9). The fluctuation range (H₂ to H₁ or H₄ to H₃) of the magnetic field intensity can be set to a desired range by changing the magnitude of currents which flow through the coils 130a and 130b so as to adjust normal magnetic fields. In addition, in a case where an ambient air temperature fluctuates in a range of T₁ to T₂, by changing the magnitudes and directions of currents which flow through the coils 130a and 130b, it is also possible to realize a temperature characteristic which increases with respect to a temperature increase and fluctuates in a range of Δf₁ to Δf₂ or a range of Δf₃ to Δf₄ (refer to graphs C and D of FIG. 9). To summarize, it is possible to randomly adjust a slope of a temperature characteristic of a frequency difference between a pair of resonance light beams by adjusting the magnitudes or directions of currents which flow through the coils 130a and 130b.

Further, it is possible to adjust intensities of magnetic fields generated by currents which flow through the coils 130a and 130b by adjusting positions or shapes (the number of turns, a diameter, and the like) of the coils 130a and 130b. Therefore, it is possible to adjust a slope of a temperature characteristic of a frequency difference between a pair of resonance light beams.

Therefore, in the atom oscillator 1 of the present embodiment, magnitudes or directions of currents which flow through the coils 130a and 130b or positions or shapes of the coils 130a and 130b are adjusted such that a slope of a temperature characteristic of a frequency difference between a pair of resonance light beams due to fluctuation of a magnetic field intensity is reverse to and is approximately the same as a slope of a temperature characteristic of a frequency difference between a pair of resonance light beams caused by an injection amount of buffer gases, a temperature characteristic of a circuit element, or the like. As a result, a frequency-temperature characteristic of the output signal of the atom oscillator 1 according to the present embodiment becomes flatter.

In addition, a heater current cannot be adjusted at random, but a direction thereof can be changed. Therefore, a polarity of a slope of a temperature characteristic of a frequency difference between a pair of resonance light beams may be changed by changing a direction of the heater current.

### Manufacturing Method of Atom Oscillator

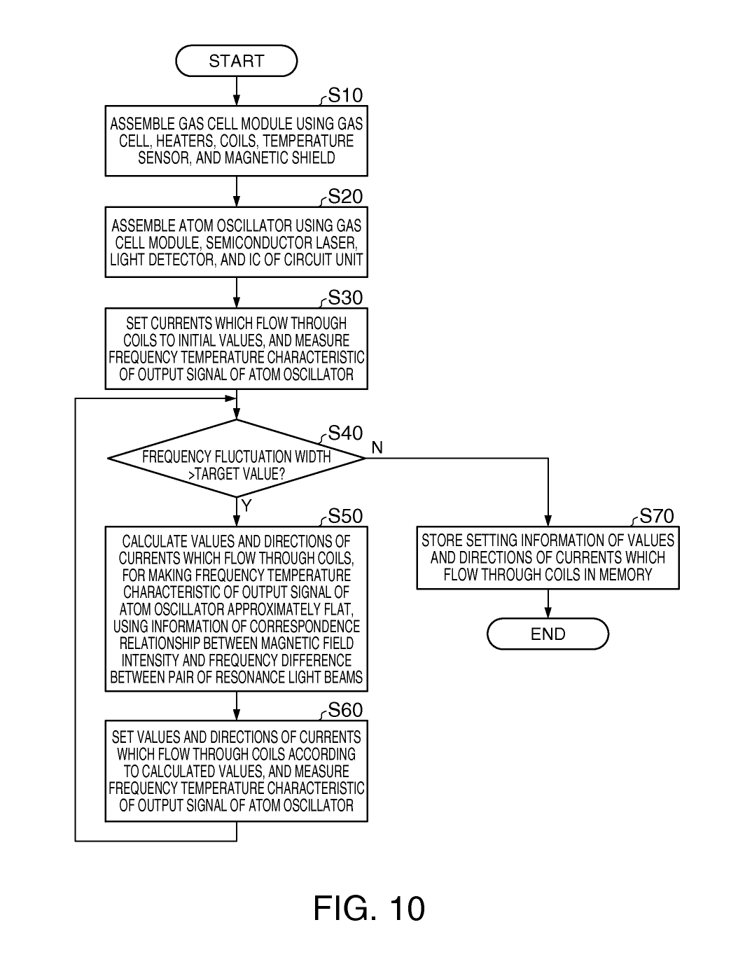

FIG. 10 is a flowchart illustrating an example of a manufacturing method of the atom oscillator 1 of the present embodiment.

First, based on design information, the gas cell module 100 is assembled using the gas cell 110, the heaters 120a and 120b, the coils 130a and 130b, the temperature sensor 140, and the magnetic shield 150 (S10).

Next, based on the design information, the atom oscillator 1 is assembled using the gas cell module 100 assembled in step S10, the semiconductor laser 200, the light detector 210, and ICs of the circuit unit (S20).

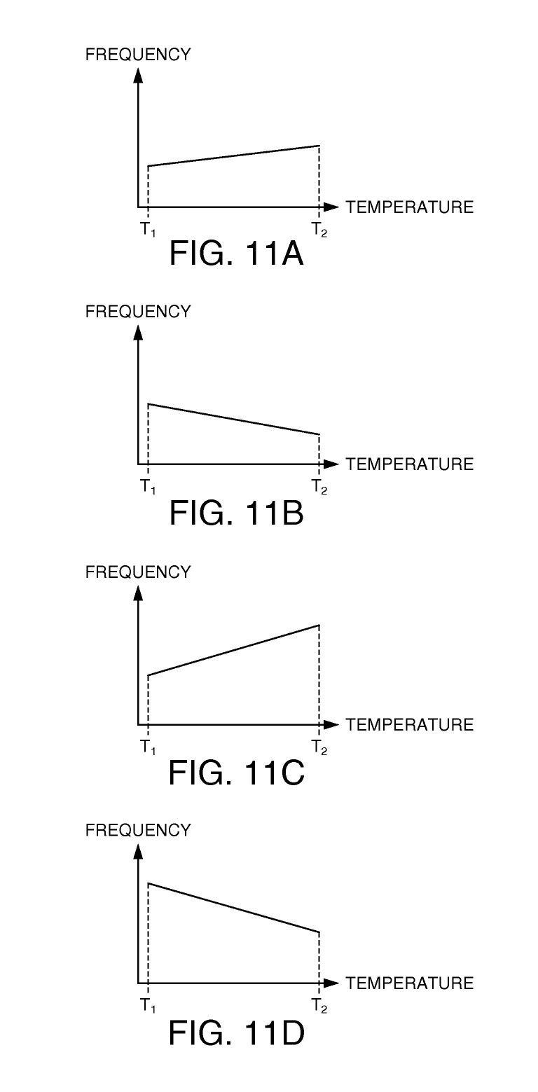

Next, currents which flow through the coils 130a and 130b are set to initial values, and a frequency-temperature characteristic of an output signal of the atom oscillator 1 is measured (S30). For example, in a case where an allowed ambient air temperature range is T₁ to T₂, an ambient temperature of the atom oscillator 1 is set to a plurality of temperatures between T₁ and T₂, and an output frequency of the atom oscillator 1 is measured at each temperature. This measurement result is plotted, and approximate calculation is performed using a method such as, for example, minimum square approximation, thereby obtaining information of a frequency-temperature characteristic (for example, a frequency-temperature characteristic shown in FIG. 11A) of an output signal of the atom oscillator 1. Further, this frequency-temperature characteristic is obtained by adding a frequency-temperature characteristic (a frequency-temperature characteristic caused by factors other than fluctuation of a magnetic field intensity) and a frequency-temperature characteristic caused by fluctuation of an intensity of a magnetic field applied to the gas cell 110.

If a frequency fluctuation width (a difference between the maximum value and the minimum value of frequencies in the allowed temperature range) of the frequency-temperature characteristic measured in step S30 is greater than a target value (Y in S40), values and directions of currents which flow through the coils 130a and 130b, for making a frequency-temperature characteristic of an output signal of the atom oscillator 1 approximately flat, are calculated using information of a correspondence relationship between the magnetic field intensity and the frequency difference between a pair of resonance light beams (S50). The information of a correspondence relationship between the magnetic field intensity and the frequency difference between a pair of resonance light beams is, for example, information as shown in FIG. 8, and it is possible to obtain information of a temperature characteristic of a frequency difference between a pair of resonance light beams caused by fluctuation of the magnetic field intensity from the information of the correspondence relationship, information of the values and directions of currents set for the coils 130a and 130b, and information of a fluctuation width of heater currents. The information of the temperature characteristic of the frequency difference between a pair of resonance light beams is converted into information of a frequency-temperature characteristic (for example, a frequency-temperature characteristic shown in FIG. 11B) of an output signal of the atom oscillator 1, and is subtracted from the frequency-temperature characteristic (for example, a frequency-temperature characteristic shown in FIG. 11A) obtained in step S30, thereby obtaining information of a frequency-temperature characteristic (for example, a frequency-temperature characteristic shown in FIG. 11C) caused by factors other than the magnetic field intensity. In addition, values and directions of currents which flow through the coils 130a and 130b are obtained through calculation in order to realize a frequency-temperature characteristic (for example, a frequency-temperature characteristic shown in FIG. 11D) caused by fluctuation of the magnetic field intensity for correcting a frequency-temperature characteristic (for example, a frequency-temperature characteristic shown in FIG. 11C) caused by factors other than the fluctuation of the magnetic field intensity by the use of the information of the correspondence relationship between the magnetic field intensity and the frequency difference between a pair of resonance light beams.

Next, values and directions of currents which flow through the coils 130a and 130b are set according to the values calculated in step S50, and a frequency-temperature characteristic of an output signal of the atom oscillator 1 is measured (S60).

In addition, if a frequency fluctuation width of the frequency-temperature characteristic measured in step S30 or S60 is equal to or less than the target value (that is, the frequency-temperature characteristic is approximately flat) (N in S40), finally, setting information of the values and directions of currents which flow through the coils 130a and 130b is stored in the memory 330 (storage unit) (S70). Therefore, the setting information of the values and directions of currents which flow through the coils 130a and 130b, stored in the memory 330 (storage unit), can be used as information for making a frequency-temperature characteristic approximately flat.

Further, in the flowchart of FIG. 10, values and directions of currents which flow through the coils 130a and 130b are adjusted, but positions or shapes of the coils 130a and 130b may be adjusted.

As described above, according to the first embodiment, by adjusting values and directions of currents which flow through the coils 130a and 130b, or positions or shapes of the coils 130a and 130b, a slope of a frequency-temperature characteristic of the atom oscillator 1 caused by fluctuation (fluctuation in a magnetic field intensity) in currents which flow through the heaters 120a and 120b is made to be reverse to a slope of a frequency-temperature characteristic of the atom oscillator 1 caused by a temperature characteristic of the gas cell 110 or the circuit unit, and thus it is possible to make a comprehensive frequency-temperature characteristic of the atom oscillator 1 flat.

### 1-2. Second Embodiment

### Functional Configuration of Atom Oscillator

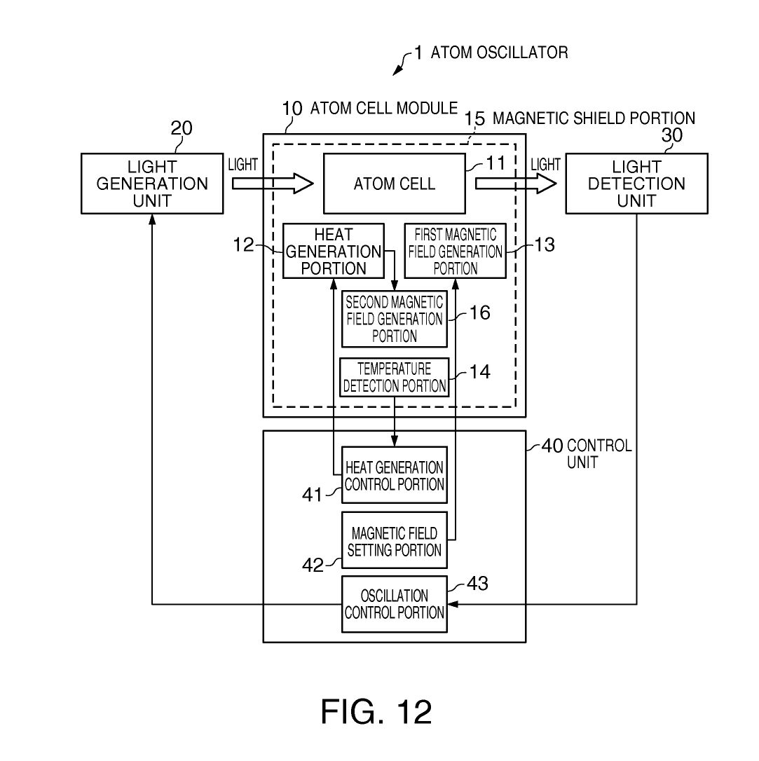

FIG. 12 is a functional block diagram of an atom oscillator according to a second embodiment. In FIG. 12, the same constituent element as in FIG. 1 is given the same reference numeral. In addition, the atom oscillator of the present embodiment may have a configuration in which some of the constituent elements (the respective portions) of FIG. 12 are appropriately omitted or changed, or other constituent elements are added.

As shown in FIG. 12, in the atom oscillator 1 according to the second embodiment, a second magnetic field generation portion 16 is added to the atom cell module 10 of the atom oscillator 1 according to the first embodiment.

The second magnetic field generation portion 16 allows at least a part of a current which flows through the heat generation portion 12 to flow therein so as to generate a magnetic field inside the atom cell 11. The second magnetic field generation portion 16 may be implemented using, for example, a coil which is wound on a part of a power supply line of the heat generation portion 12. A direction or an intensity of a magnetic field generated by the coil can be adjusted to a desired state by selecting a position or a shape (the number of turns of the coil, a diameter, or the like) of the coil, or a direction of a current which flows through the coil (or a coil winding direction).

The other functional configurations of the atom oscillator 1 according to the second embodiment are the same as in the first embodiment, and thus description thereof will be omitted.

### Specific Configuration of Atom Oscillator

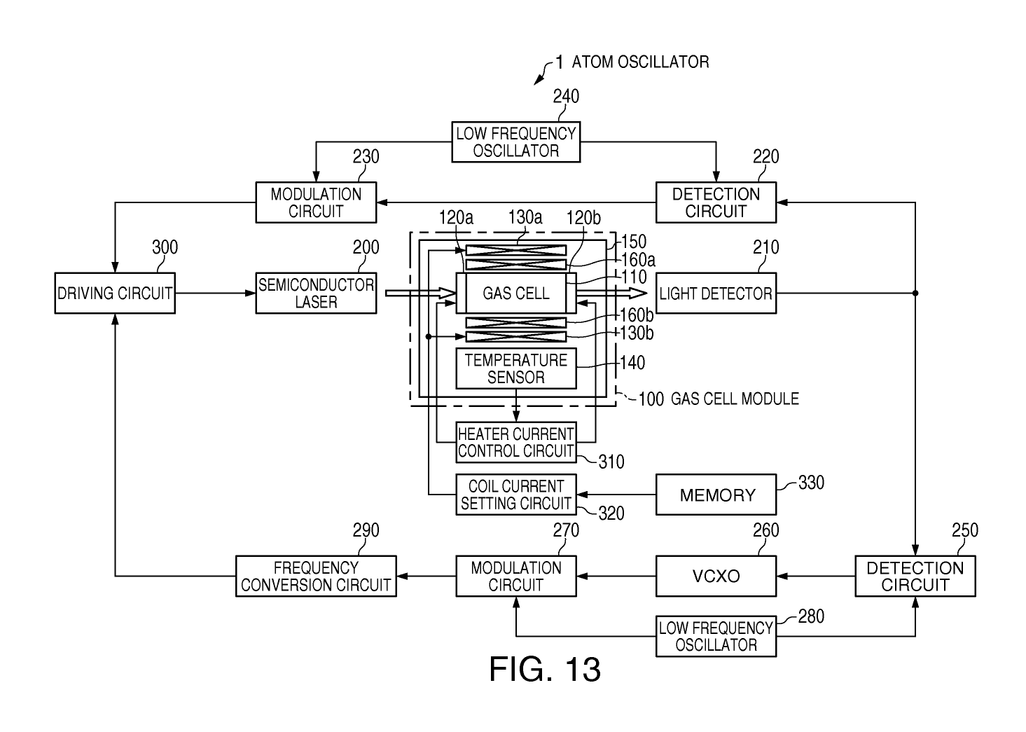

FIG. 13 is a specific configuration example of the atom oscillator 1 according to the second embodiment. In FIG. 13, the same constituent element as in FIG. 2 is given the same reference numeral. In addition, the atom oscillator according to the present embodiment may have a configuration in which some of the constituent elements (the respective portions) of FIG. 13 may be omitted or changed, or other constituent elements may be added.

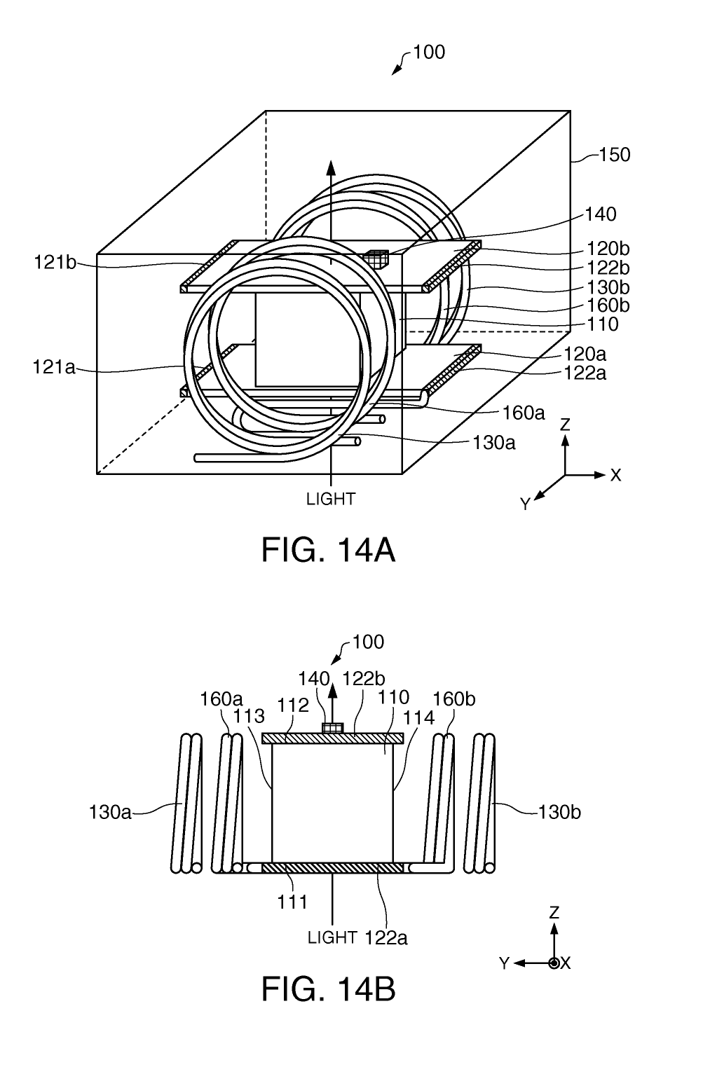

As shown in FIG. 13, in the atom oscillator 1 according to the second embodiment, two coils 160a and 160b are added to the gas cell module 100 of the atom oscillator 1 according to the first embodiment. FIGS. 14A and 14B show an example of a structure of the gas cell module 100 according to the present embodiment. FIG. 14A is a perspective view of the gas cell module 100, and FIG. 14B is a side view of the gas cell module 100. In FIGS. 14A and 14B, for convenience of description, three axes (the X axis, the Y axis, and the Z axis) perpendicular to one another are shown together, and FIG. 14B is a side view of the gas cell module 100 when viewed from the positive direction of the X axis.

Structures and arrangements of the gas cell 110, the heaters 120a and 120b, and the temperature sensor 140 are the same as in the first embodiment, and description thereof will be omitted.

The two coils 160a and 160b are disposed so as to face two surfaces 113 and 114 perpendicular to (perpendicular to the Y axis) both of the incidence surface 111 and the emission surface 112 of the gas cell 110 respectively. One end of the coil 160a is connected to the electrode 122a of the heater 120a. In addition, one end of the coil 160b is connected to the electrode 121a of the heater 120a. Further, under the control of the heater current control circuit 310 of FIG. 13, a current with the magnitude according to an output signal of the temperature sensor 140 flows through the coil 160a, then flows through the heater 120a from the electrode 122a to the electrode 121a, and further flows through the coil 160b. The two coils 160a and 160b correspond to the second magnetic field generation portion 16 of FIG. 12, and magnetic fields according to directions and magnitudes of heater currents are generated inside the gas cell 110 by the current which flows through the two coils 160a and 160b. Since the heater current fluctuates depending on fluctuation in an ambient air temperature, the magnetic fields generated by the coils 160a and 160b fluctuate in a range depending on a fluctuation range of the ambient air temperature.

Further, in the present embodiment, the overall current which flows through the heater 120a flows through the coils 160a and 160b, but there may be a structure in which only a part of the current which flows through the heater 120a may be divided and flow through the coils 160a and 160b.

In addition, in the present embodiment, the coils 160a and 160b are not electrically connected to the heater 120b, and a current with the magnitude according to an output signal of the temperature sensor 140 is directly supplied to the heater 120b from the heater current control circuit 310 in a direction of the electrode 121b from the electrode 122b or a reverse direction thereof. However, the heater 120b may be electrically connected to at least one of the coils 160a and 160b.

The two coils 130a and 130b are respectively disposed so as to face the coils 160a and 160b. The two coils 130a and 130b correspond to the first magnetic field generation portion 13 of FIG. 12, and constant magnetic fields (normal magnetic fields) according to directions and magnitudes of currents which flow through the two coils 130a and 130b are generated at respective positions inside the gas cell 110. However, magnetic fields according to heater currents which fluctuate depending on an ambient air temperature are also generated at the respective positions inside the gas cell 110, and thus the magnetic fields at the respective positions inside the gas cell 110 fluctuate in a range depending on a fluctuation range of the ambient air temperature.

The other specific configurations of the atom oscillator 1 according to the second embodiment are the same as in the first embodiment, and thus description thereof will be omitted.

### Frequency-Temperature Characteristic of Atom Oscillator

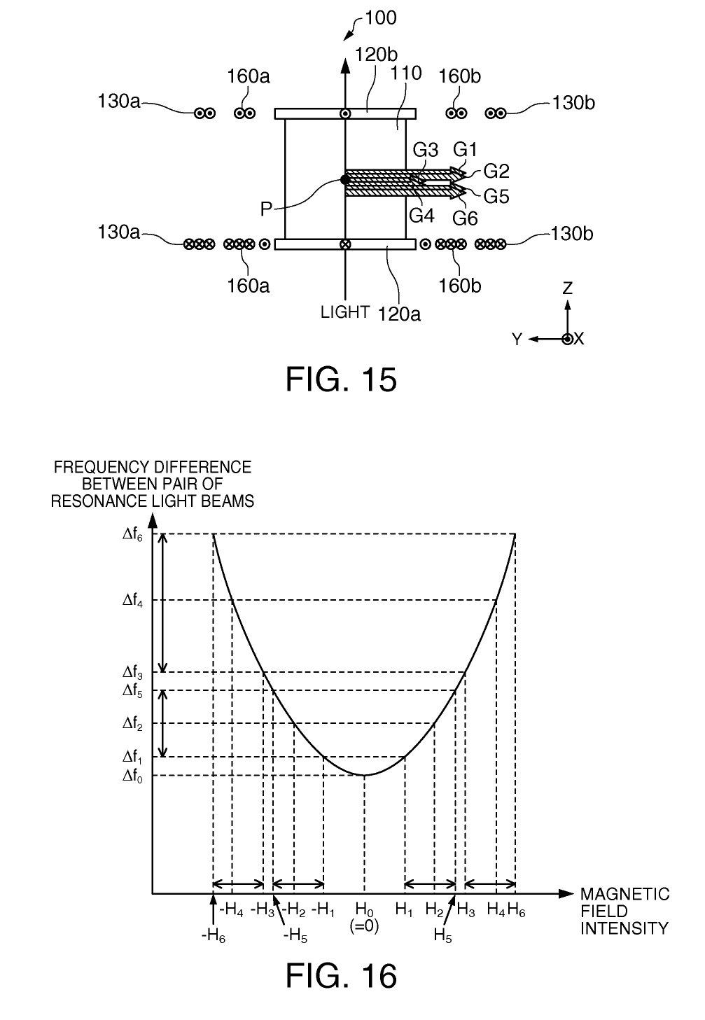

FIG. 15 is a diagram illustrating an example of a relationship between directions of currents which flow through the heaters 120a and 120b, the coils 130a and 130b, and the coils 160a and 160b, and directions of magnetic fields generated inside the gas cell 110. FIG. 15 is a cross-sectional view which is viewed from the positive direction of the X axis when the gas cell module 100 of FIGS. 14A and 14B is cut at a surface which is parallel to the YZ plane and includes a light path. In addition, in FIG. 15, the magnetic shield 150 is not shown.

As shown in FIG. 15, a current flows through the coil 130a clockwise when viewed from, for example, the +Y direction, and thus a magnetic field G1 in the −Y direction is generated at a point P (for example, a central position inside the gas cell 110) on the light path inside the gas cell 110. Similarly, a current also flows through the coil 130b clockwise when viewed from the +Y direction, and thus a magnetic field G2 in the −Y direction is generated at the point P.

A current flows through the heater 120a, for example, in the −X direction (from the electrode 122a to the electrode 121a), and thus a magnetic field G3 in the −Y direction is generated at the point P. On the other hand, a current flows through the heater 120b, for example, in the +X direction (from the electrode 121b to the electrode 122b), and thus a magnetic field G4 in the −Y direction is generated at the point P.

A current flows through the coil 160a clockwise when viewed from, for example, the +Y direction, and thus a magnetic field G5 in the −Y direction is generated at the point P. Similarly, a current also flows through the heater 160b clockwise when viewed from the +Y direction, and thus a magnetic field G6 in the −Y direction is generated at the point P.

According to the quantum interference device of this application example, the directions of the magnetic fields (normal magnetic fields) G1 and G2 generated by the currents which flow through the coils 130a and 130b are the same as the directions of the magnetic fields (varying fields) G3 and G4 generated by the currents (heater currents) which flow through the heaters 120a and 120b and the directions of the magnetic fields (varying magnetic fields) G5 and G6 generated by the currents which flow through the coils 160a and 160b.

Here, since the magnetic fields G1 and G2 are constant even if an ambient air temperature varies, but the magnetic fields G3, G4, G5, and G6 approximately linearly decreases with respect to a temperature increase, a sum total G1+G2+G3+G4+G5+G6 of the magnetic fields applied to the point P inside the gas cell 110 also approximately linearly decreases with respect to a temperature increase.

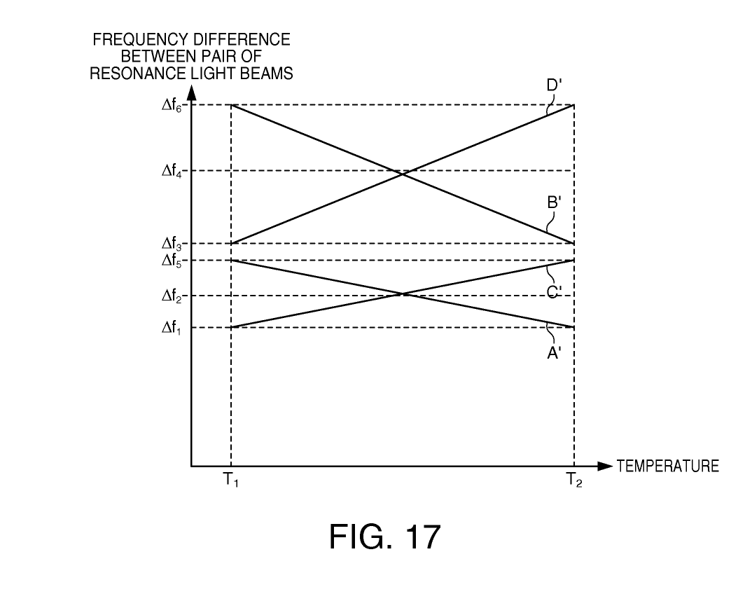

In addition, in a case where an ambient air temperature fluctuates in a range of T₁ to T₂, for example, as shown in FIG. 16, a magnetic field intensity (the magnitude of G1+G2+G3+G4+G5+G6) at the point P fluctuates in a range of H₅ to H₁, and a frequency difference between a pair of resonance light beams fluctuates in a range of Δf₅ to Δf₁ (refer to a graph A′ of FIG. 17). In addition, for example, a magnetic field intensity at the point P fluctuates in a range of H₆ to H₃, and a frequency difference between a pair of resonance light beams fluctuates in a range of Δf₆ to Δf₃ (refer to a graph B′ of FIG. 17). Further, in a case where an ambient air temperature fluctuates in a range of T₁ to T₂ by changing the magnitudes and directions of currents which flow through the coils 130a and 130b, it is also possible to realize a temperature characteristic which increases with respect to a temperature increase and fluctuates in a range of Δf₁ to Δf₅ or a range of Δf₃ to Δf₆ (refer to graphs C′ and D′ of FIG. 17). Here, a fluctuation range of the magnetic field intensity at the point P is wider than in the first embodiment by a fluctuation amount of G5+G6, and thus absolute values of slopes of the graphs A′, B′, C′ and D′ of FIG. 17 are larger than absolute values of slopes of the graphs A, B, C and D of FIG. 9. To summarize, the coils 160a and 160b are provided, and thereby a slope of a temperature characteristic of a frequency difference between a pair of resonance light beams is steeper than a case where the coils 160a and 160b are not provided (the first embodiment).

In addition, if changing is performed such that the coil 160a is connected to the electrode 121a of the heater 120a, and the coil 160b is connected to the electrode 122a of the hater 120a, or changing is performed such that the coils 160a and 160b are wound in an opposite direction to FIGS. 14A and 14B, directions of the magnetic fields G5 and G6 at the point P are reverse to the directions of the magnetic fields G3 and G4, and thus a fluctuation range of the magnetic field intensity at the point P can be narrowed by a fluctuation amount of G5+G6 as compared with the first embodiment. In other words, the coils 160a and 160b are provided, and thereby a slope of a temperature characteristic of a frequency difference between a pair of resonance light beams can be gentler than a case where the coils 160a and 160b are not provided (the first embodiment).

Further, it is possible to adjust a fluctuation amount of magnetic fields generated by heater currents which flow through the coils 160a and 160b by adjusting positions or shapes (the number of turns, a diameter, and the like) of the coils 160a and 160b. For example, in a case where a current flows in the direction FIG. 15, when the coils 160a and 160b have five turns and ten turns, the latter can further widen (make a slope of a temperature characteristic of a frequency difference between a pair of resonance light beams steeper) a fluctuation range of a magnetic field.

Therefore, in the atom oscillator 1 of the present embodiment, not only magnitudes or directions of currents which flow through the coils 130a and 130b or positions or shapes of the coils 130a and 130b but also magnitudes or directions of currents which flow through the coils 160a and 160b or positions or shapes of the coils 160a and 160b are adjusted such that a slope of a temperature characteristic of a frequency difference between a pair of resonance light beams due to fluctuation of a magnetic field intensity is reverse to and is approximately the same as a slope of a temperature characteristic of a frequency difference between a pair of resonance light beams caused by an injection amount of buffer gases, a temperature characteristic of a circuit element, or the like. As a result, a frequency-temperature characteristic of an output signal of the atom oscillator 1 according to the present embodiment becomes flatter.

### Manufacturing Method of Atom Oscillator

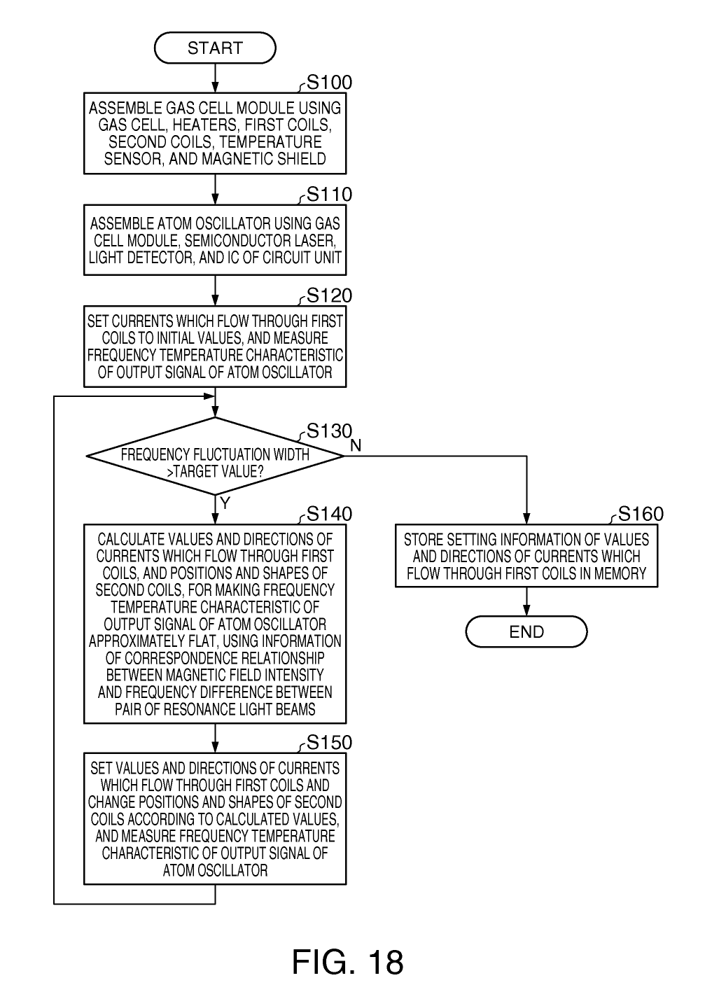

FIG. 18 is a flowchart illustrating an example of a manufacturing method of the atom oscillator 1 of the present embodiment.

First, based on design information, the gas cell module 100 is assembled using the gas cell 110, the heaters 120a and 120b, the coils 130a and 130b (first coils), the coils 160a and 160b (second coils), the temperature sensor 140, and the magnetic shield 150 (S100).

Next, based on the design information, the atom oscillator 1 is assembled using the gas cell module 100 assembled in step S100, the semiconductor laser 200, the light detector 210, and ICs of the circuit unit (S110).

Next, currents which flow through the coils 130a and 130b (the first coils) are set to initial values, and a frequency-temperature characteristic of an output signal of the atom oscillator 1 is measured (S120).

If a frequency fluctuation width (a difference between the maximum value and the minimum value of frequencies in the allowed temperature range) of the frequency-temperature characteristic measured in step S120 is greater than a target value (Y in S130), values and directions of currents which flow through the coils 130a and 130b (the first coils), and positions and shapes (the number of turns, a diameter, or the like) of the coils 160a and 160b (the second coils), for approximately flattening a frequency-temperature characteristic of an output signal of the atom oscillator 1, are calculated using information of a correspondence relationship between the magnetic field intensity and the frequency difference between a pair of resonance light beams (S140).

Next, values and directions of currents which flow through the coils 130a and 130b (the first coils) are set and positions and shapes of the coils 160a and 160b (the second coils) are changed, according to the values calculated in step S140, and a frequency-temperature characteristic of an output signal of the atom oscillator 1 is measured (S150).

In addition, if a frequency fluctuation width of the frequency-temperature characteristic measured in step S120 or S150 is equal to or less than the target value (N in S130), finally, setting information of the values and directions of currents which flow through the coils 130a and 130b (the first coils) is stored in the memory 330 (S160).

Further, in the flowchart of FIG. 18, values and directions of currents which flow through the coils 130a and 130b (the first coils) are adjusted, but positions or shapes of the coils 130a and 130b (the first coils) may be adjusted. In addition, in the flowchart of FIG. 18, positions or shapes (the number of turns, a diameter, or the like) of the coils 160a and 160b (the second coils) are adjusted, but values of currents which flow through the coils 160a and 160b (the second coils) may be adjusted.

In addition, in the flowchart of FIG. 18, both of the coils 130a and 130b (the first coils) and the coils 160a and 160b (the second coils) are adjusted, but either one may be adjusted.

As described above, according to the second embodiment, the coils 160a and 160b are provided, and thereby a slope of a frequency-temperature characteristic of the atom oscillator 1 caused by fluctuation (fluctuation in a magnetic field intensity) in a current which flows through the heaters 120a and 120b can be increased and decreased. Therefore, it is possible to more effectively make a frequency-temperature characteristic of the atom oscillator 1 flat even in a case where it is difficult to make the frequency-temperature characteristic of the atom oscillator 1 flat only with adjustment of the coils 130a and 130b.

### 2. Electronic Apparatus

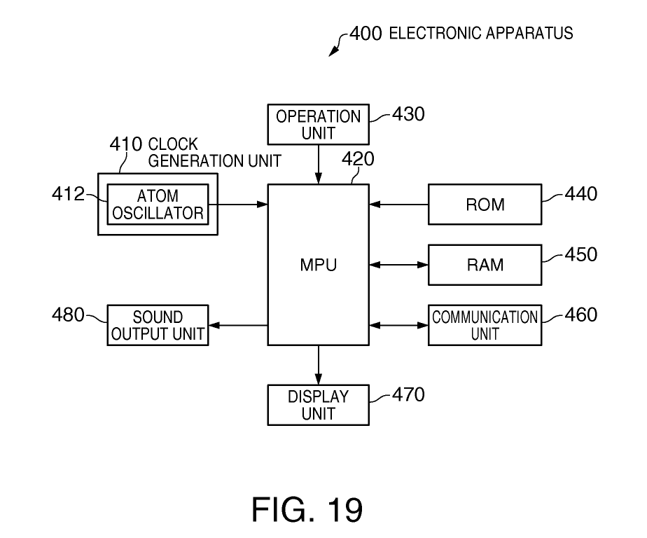

FIG. 19 is a functional block diagram of an electronic apparatus according to the present embodiment. An electronic apparatus 400 according to the present embodiment includes a clock generation unit 410, a micro processing unit (MPU) 420, an operation unit 430, a read only memory (ROM) 440, a random access memory (RAM) 450, a communication unit 460, a display unit 470, and a sound output unit 480. In addition, the electronic apparatus of the present embodiment may have a configuration in which some of the constituent elements (the respective portions) of FIG. 19 are omitted or changed, or other constituent elements are added.

The clock generation unit 410 generates various clock signals by using an oscillation signal of an atom oscillator 412 as an atom oscillation clock. The atom oscillator 412 is, for example, the atom oscillator 1 according to the above-described embodiments.

The MPU 420 performs various calculation processes or control processes by the use of the various clock signals generated by the clock generation unit 410 according to a program stored in the ROM 440 or the like. Specifically, the MPU 420 performs various processes corresponding to an operation signal from the operation unit 430, a process of controlling the communication unit 460 for performing data communication with an external device, a process of transmitting display signals for displaying a variety of information on the display unit 470, a process of making the sound output unit 480 output a variety of sound, and the like.

The operation unit 430 is an input device formed by operation keys or button switches, and outputs an operation signal corresponding to an operation by a user to the MPU 420.

The ROM 440 stores programs, data, and the like for the MPU 420 to perform various calculation processes or control processes.

The RAM 450 is used as a work area of the MPU 420, and temporarily stores a program or data read from the ROM 440, data input from the operation unit 430, calculation results executed by the MPU 420 according to various programs, and the like.

The communication unit 460 performs a variety of control for establishing data communication between the MPU 420 and an external device.

The display unit 470 is a display device formed by an liquid crystal display (LCD) or the like, and displays a variety of information on the basis of display signals input from the MPU 420.

The sound output unit 480 is a device which outputs sound of a speaker or the like.

The atom oscillator 1 of the present embodiment is incorporated as the atom oscillator 412, and thus it is possible to realize an electronic apparatus with higher reliability.

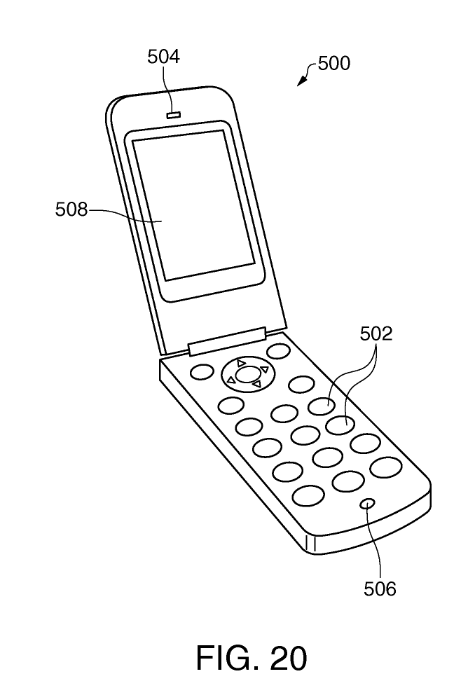

FIG. 20 is a schematic diagram of an electronic apparatus (portable terminal) which has the atom oscillator mounted therein as an example of the electronic apparatus of the present embodiment. In FIG. 20, a portable terminal 500 (including a PHS and a smart phone) (an example of the electronic apparatus 400) includes a plurality of operation buttons 502 (an example of the operation unit 430), an ear piece 504, and a mouth piece 506, and a display unit 508 (an example of the display unit 470) is disposed between the operation buttons 502 and the ear piece 504. In recent years, this portable terminal 500 also has a GPS function. Therefore, the atom oscillator of the present embodiment is embedded in the portable terminal 500 as a clock source of a GPS circuit.

Other various electronic apparatuses are considered as the electronic apparatus of the present embodiment, and may include, for example, a personal computer (for example, a mobile type personal computer, a laptop type personal computer, or a tablet type personal computer), a mobile terminal such as a mobile phone, a digital still camera, an ink jet type ejection apparatus (for example, an ink jet printer), a storage area network apparatus such as a router or a switch, a local area network apparatus, a television, a video camera, a video tape recorder, a car navigation apparatus, a pager, an electronic organizer (including a communication function portion), an electronic dictionary, an electronic calculator, an electronic gaming machine, a gaming controller, a word processor, a workstation, a videophone, a security television monitor, an electronic binocular, a POS terminal, a medical apparatus (for example, an electronic thermometer, a sphygmomanometer, a blood glucose monitoring system, an electrocardiographic apparatus, an ultrasonic diagnostic apparatus, or an electronic endoscope), a fish-finder, various measurement apparatuses, meters and gauges (for example, meters and gauges of vehicles, aircrafts, and ships), a flight simulator, a head mount display, a motion trace, a motion tracking, a motion controller, a pedestrian dead reckoning (PDR), and the like.

### 3. Modification Examples

The invention is not limited to the present embodiment, and may have various modification examples within the scope of the spirit of the invention.

### Modification Example 1

In the atom oscillator of the present embodiment, there may be a modification in which control is performed on a wavelength λ₁ (a frequency f₁) corresponding to an energy difference between the excitation level and one ground level of the alkali metal atom sealed in the gas cell 110 and a wavelength λ₂ (a frequency f₂) corresponding to an energy difference between the excitation level and the other ground level through the first feedback loop such that a central wavelength λ₀ (a central frequency f₀) of emission light of the semiconductor laser 200 is substantially the same as λ₁ or λ₂ (the central frequency f₀ is the substantially the same as f₁ or f₂), and the frequency conversion circuit 290 converts an output signal of the modulation circuit 270 into a signal with the same frequency as a frequency corresponding to ΔE₁₂ through the second feedback loop.

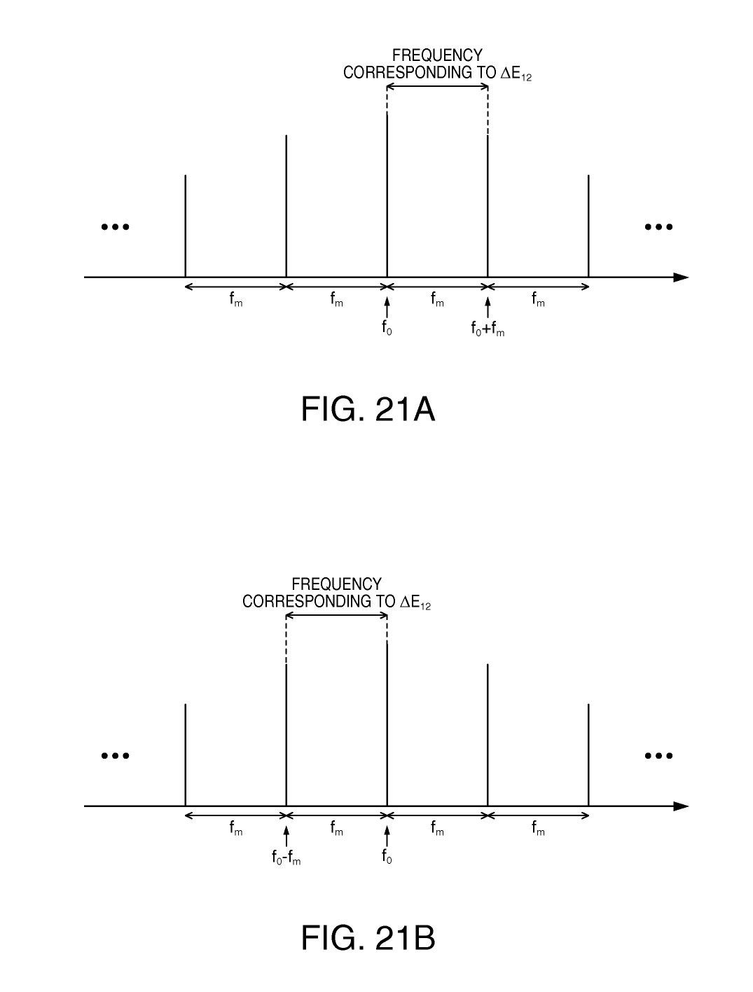

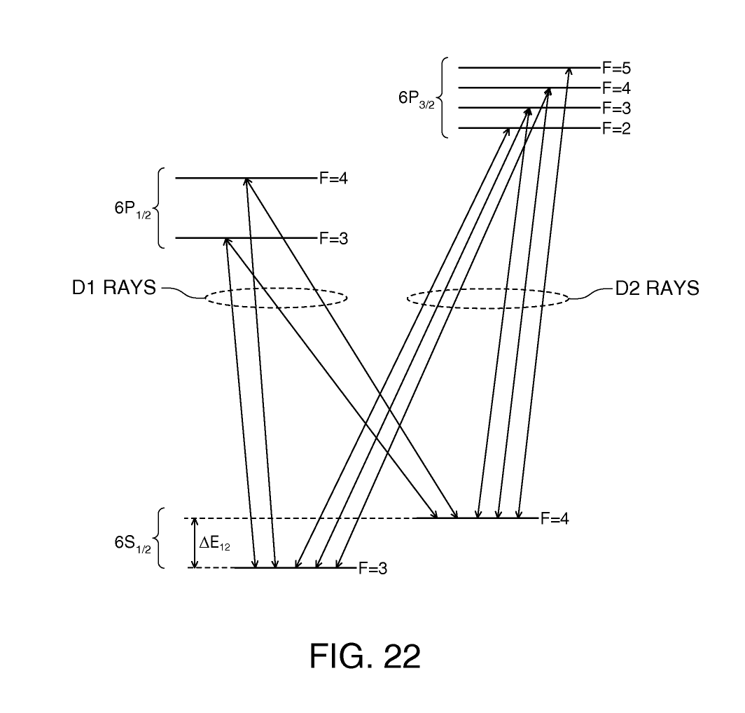

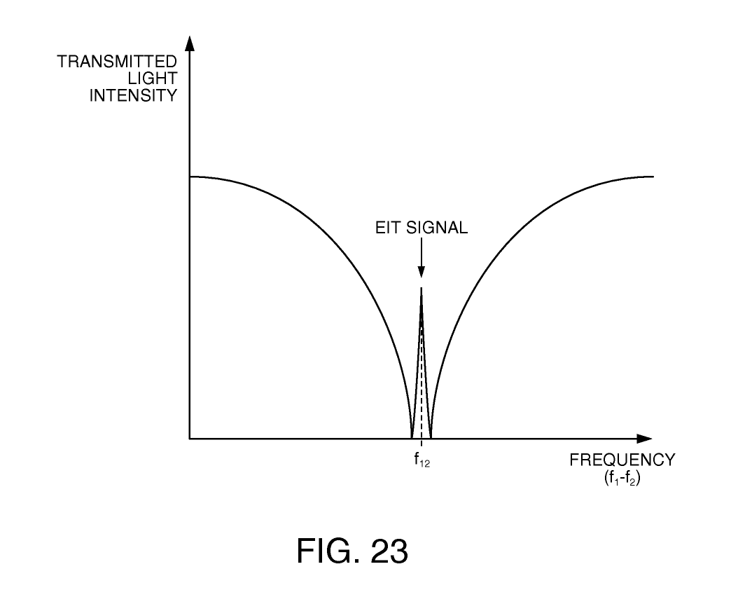

FIG. 21A is a schematic diagram illustrating frequency spectra of emission light of the semiconductor laser 200 in a case where the central wavelength λ₀ matches a wavelength λ₂, and FIG. 21B is a schematic diagram illustrating frequency spectra of emission light of the semiconductor laser 200 in a case where the central wavelength λ₀ matches a wavelength λ₁. In FIGS. 21A and 21B, the transverse axis expresses a frequency of light, and the longitudinal axis expresses an intensity of light. In a case of FIG. 21A, a frequency difference fₘ between light with a frequency f₀+fₘ and light with a frequency f₀ is the same as a frequency corresponding to ΔE₁₂, the frequency f₀+fₘ is approximately the same as the frequency f₁, and the frequency f₀ is approximately the same as the frequency f₂. Therefore, the light with the frequency f₀+fₘ and the light with the frequency f₀ become a pair of resonance light beams which cause an EIT phenomenon in the alkali metal atom sealed in the gas cell 110. On the other hand, in a case of FIG. 21B, a frequency difference fₘ between light with a frequency f₀ and light with a frequency f₀−fₘ is the same as a frequency corresponding to ΔE₁₂, the frequency f₀ is approximately the same as the frequency f₁, and the frequency f₀−fₘ is approximately the same as the frequency f₂. Therefore, the light with the frequency f₀ and the light with the frequency f₀-fₘ become a pair of resonance light beams which cause an EIT phenomenon in the alkali metal atom sealed in the gas cell 110.

### Modification Example 2

The atom oscillator of the present embodiment may be modified to a configuration using an electro-optic modulator (EOM). That is, the semiconductor laser 200 generates light with a single frequency f₀ according to a set bias current without performing modulation using an output signal (modulated signal) of the frequency conversion circuit 290. The light with the frequency f₀ is incident on the electro-optic modulator (EOM) so as to perform modulation using an output signal (modulated signal) of the frequency conversion circuit 290. As a result, it is possible to generate light having the same frequency spectra as in FIG. 5. In addition, the gas cell 110 is irradiated with light generated by the electro-optic modulator (EOM). In this atom oscillator, a configuration formed by the semiconductor laser 200 and the electro-optic modulator (EOM) corresponds to the light generation unit 20 of FIG. 1 or FIG. 12.

Further, an acousto-optic modulator (AOM) may be used instead of the electro-optic modulator (EOM).

### 4. Applications

The configuration of the atom oscillator of the present embodiment or the modification example is applicable to various quantum interference devices which cause a quantum interference state in an atom by using resonance light.

### Application 1

For example, in the atom oscillator of the present embodiment or the modification example, the magnetic shield 150 is omitted, and thereby an oscillation frequency of the voltage controlled crystal oscillator (VCXO) 260 varies following a variation in a peripheral magnetic field of the gas cell module 100. Therefore, it is possible to implement a magnetic sensor (an example of the quantum interference device) by disposing a magnetic measurement object around the gas cell module 100.

### Application 2

In addition, for example, since a very stable quantum interference state (quantum coherence state) of a metal atom can be generated with the same configuration as the atom oscillator of the present embodiment or the modification example, it is possible to implement alight source (an example of the quantum interference device) used in quantum information apparatuses such as a quantum computer, a quantum memory, and a quantum cryptosystem by extracting a pair of resonance light beams incident on the gas cell 110.

The above-described embodiments and modification examples are only an example, and the invention is not limited thereto. For example, the respective embodiments and modification examples may be appropriately combined.

The invention includes substantially the same configuration (for example, a configuration in which a function, a method, and a result are the same, or a configuration in which an object and an effect are the same) as the configuration described in the embodiments. In addition, the invention includes a configuration in which an unessential part of the configuration described in the embodiments is replaced. Further, the invention includes a configuration which achieves the same operation and effect or can achieve the same object as the configuration described in the embodiments. Furthermore, the invention includes a configuration in which a well-known technique is added to the configuration described in the embodiments.

The entire disclosure of Japanese Patent Application No. 2012-198265, filed Sep. 10, 2012 is expressly incorporated by reference herein.

What is claimed is:

1. A manufacturing method of a quantum interference device including an atom cell in which an atom is sealed, a light generation unit that generates light including a pair of resonance light beams and irradiates the atom cell with the light, a light detection unit that detects light transmitted through the atom cell, a control unit that controls frequencies of the pair of resonance light beams on the basis of a detection signal of the light detection unit, a heat generation unit that heats the atom cell, and a first magnetic field generation unit that generates a magnetic field inside the atom cell, the method comprising:
assembling the quantum interference device including the atom cell, the light generation unit, the light detection unit, the control unit, the heat generation unit, and the first magnetic field generation unit; and
adjusting at least one of a current which flows through the first magnetic field generation unit, and a position and a shape of the first magnetic field generation unit such that a frequency-temperature characteristic of the quantum interference device becomes approximately flat.

2. The manufacturing method of the quantum interference device according to claim 1, further comprising:
measuring a frequency-temperature characteristic of the quantum interference device assembled in the assembling of the quantum interference device,
wherein, in the adjusting, a value of a current which flows through the first magnetic field generation unit is calculated based on a measurement result in the measuring, and information which can specify a correspondence relationship between a magnetic field generated by the first magnetic field generation unit and frequencies of the pair of resonance light beams.

3. The manufacturing method of the quantum interference device according to claim 1,
wherein the quantum interference device further includes a second magnetic field generation unit that generates a magnetic field inside the atom cell by using a current which flows through the heat generation unit, and
wherein, in the assembling, the atom cell, the light generation unit, the light detection unit, the control unit, the heat generation unit, the first magnetic field generation unit, and the second magnetic field generation unit are respectively disposed at desired positions so as to assemble the quantum interference device.

4. The manufacturing method of the quantum interference device according to claim 3, wherein, in the adjusting, the quantum interference device adjusts at least one of a current which flows through the second magnetic field generation unit, and a position and a shape of the second magnetic field generation unit such that a frequency-temperature characteristic of the quantum interference device becomes approximately flat.

5. A quantum interference device which causes a quantum interference state in an atom by using a pair of resonance light beams, comprising:
an atom cell in which the atom is sealed;
a light generation unit that generates light including the pair of resonance light beams and irradiates the atom cell with the light;
a light detection unit that detects light transmitted through the atom cell;
a control unit that controls frequencies of the pair of resonance light beams on the basis of a detection signal of the light detection unit;
a heat generation unit that heats the atom cell;
a first magnetic field generation unit that generates a magnetic field inside the atom cell; and
a storage unit that stores setting information of a value and a direction of a current which flows through the first magnetic field generation unit for making a frequency-temperature characteristic approximately flat.

6. An electronic apparatus comprising the quantum interference device according to claim 5.

7. An atom cell module comprising:
an atom cell in which an atom is sealed;
a heat generation unit that heats the atom cell; and
a first magnetic field generation unit that generates a magnetic field inside the atom cell,
wherein at least one of a current which flows through the first magnetic field generation unit, and a position and a shape of the first magnetic field generation unit is adjusted such that a frequency-temperature characteristic of a pair of resonance light beams causing a quantum interference state in the atom becomes approximately flat.
